(19) United States
(12) Patent Application Publication
(10) Pub. No.: US 2024/0251630 A1
(43) Pub. Date: Jul. 25, 2024

(54) ELECTRONIC DEVICE

(71) Applicant: SAMSUNG DISPLAY CO., LTD., YONGIN-SI (KR)

(72) Inventors: BOKWANG SONG, YONGIN-SI (KR); KWANG SOO BAE, YONGIN-SI (KR); CHEOL-GON LEE, YONGIN-SI (KR); MIN OH CHOI, YONGIN-SI (KR); SOO YEONG HONG, YONGIN-SI (KR)

(21) Appl. No.: 18/510,287

(22) Filed: Nov. 15, 2023

(30) Foreign Application Priority Data
Jan. 19, 2023 (KR) 10-2023-0008294

(51) Int. Cl. H10K 59/60; H10K 59/122; H10K 59/131

(52) U.S. Cl. CPC H10K 59/60; H10K 59/122; H10K 59/131; H10K 59/40

(57) ABSTRACT

An electronic device includes a display panel including a transmission area and a display area disposed adjacent to the transmission area. An image is displayed in the display area. The electronic device further includes an optical sensor overlapping the transmission area and disposed under the display panel. The display panel includes a light emitting element and a light receiving element, which are disposed in the display area, signal lines electrically connected to the light emitting element or the light receiving element, and a connection line disposed along a periphery of the transmission area. At least one of the signal lines includes a first line and a second line spaced apart from the first line with the transmission area interposed therebetween, and the connection line is connected to each of the first line and the second line.

### CROSS-REFERENCE TO RELATED APPLICATIONS

This U.S. non-provisional patent application claims priority under 35 U.S.C. § 119 to Korean Patent Application No. 10-2023-0008294, filed on Jan. 19, 2023, the disclosure of which is incorporated by reference herein in its entirety.

### TECHNICAL FIELD

Embodiments of the present disclosure relate to an electronic device. More particularly, embodiments of the present disclosure relate to an electronic device including a light receiving element.

### DISCUSSION OF RELATED ART

Multimedia electronic devices, such as televisions, mobile phones, tablet computers, navigation devices, game devices, etc., typically include a display device that displays an image and an input sensing device that senses an external input. Such multimedia electronic devices may further include various functions to sense biometric information of a user.

As a biometric information recognition method, a capacitive method that senses a variation in capacitance between electrodes, an optical sensing method that senses an incident light using an optical sensor, or an ultrasonic method that senses a vibration using a piezoelectric material, may be used.

### SUMMARY

Embodiments of the present disclosure provide an electronic device capable of sensing biometric information using a light receiving element disposed under a display panel while sensing an external environment using an optical sensor disposed under the display panel.

Embodiments of the present disclosure provide an electronic device with increased light transmittance of a transmission area of a display panel corresponding to an optical sensor.

Embodiments of the present disclosure provide an electronic device including a display panel including a transmission area and a display area disposed adjacent to the transmission area. An image is displayed in the display area. The electronic device further includes an optical sensor overlapping the transmission area and disposed under the display panel. The display panel includes a light emitting element disposed in the display area, a light receiving element disposed in the display area, a plurality of signal lines electrically connected to the light emitting element or the light receiving element, and a connection line disposed along a periphery of the transmission area. At least one of the signal lines includes a first line and a second line spaced apart from the first line with the transmission area interposed therebetween, and the connection line is connected to each of the first line and the second line.

In an embodiment, the connection line extends along one side of the transmission area.

In an embodiment, the connection line has a closed-line shape surrounding the transmission area.

In an embodiment, the connection line includes a metal material.

In an embodiment, the connection line includes an optically transparent conductive material.

In an embodiment, the connection line includes the same material as the first and second lines.

In an embodiment, the first line and the second line are disposed on the same layer, and the connection line is disposed on a layer different from the first and second lines and connected to each of the first and second lines via a contact hole.

In an embodiment, the light emitting element includes a plurality of light emitting elements, and the transmission area is disposed between the light emitting elements.

In an embodiment, the light receiving element is one of a plurality of light receiving elements, and each of the light receiving elements is disposed between the light emitting elements and spaced apart from the transmission area.

In an embodiment, the light emitting element includes a first electrode, a second electrode disposed on the first electrode, and a light emitting layer disposed between the first electrode and the second electrode. The light receiving element includes a sensing anode electrode disposed on the same layer as the first electrode, a sensing cathode electrode disposed on the sensing anode electrode, and a photoelectric conversion layer disposed between the sensing anode electrode and the sensing cathode electrode.

In an embodiment, the display panel further includes a pixel definition layer through which a light emitting opening, a light receiving opening, and a transmission opening, which are spaced apart from each other, are defined, the light emitting element corresponds to the light emitting opening, the light receiving element corresponds to the light receiving opening, and the transmission opening overlaps the transmission area.

In an embodiment, the signal lines include a data line electrically connected to the light emitting element and a read-out line electrically connected to the light receiving element, each of the data line and the read-out line extends in one direction, and the data line and the read-out line are arranged spaced apart from each other in a direction intersecting the one direction.

In an embodiment, the data line and the read-out line are disposed on the same layer.

In an embodiment, the first line and the second line are connected to each other via the connection line, and the first line and the second line correspond to the read-out line.

Embodiments of the present disclosure provide an electronic device including a display panel including a transmission area and an optical sensor overlapping the transmission area. The display panel includes a circuit layer and an element layer disposed on the circuit layer and including a plurality of light emitting elements and a plurality of light receiving elements. The circuit layer includes a pixel driving circuit electrically connected to each of the light emitting elements, a sensor driving circuit electrically connected to each of the light receiving elements, a data line electrically connected to the pixel driving circuit, a read-out line electrically connected to the sensor driving circuit, and a connection line connected to the read-out line. The transmission area is disposed between the light emitting elements when viewed in a plane and spaced apart from the pixel driving circuit, the sensor driving circuit, the data line, the read-out line, and the connection line, and the connection line is disposed along a periphery of the transmission area.

In an embodiment, the display panel further includes a display area in which an image is displayed, and the data line and the read-out line extend in one direction in a display area and are spaced apart from each other in a direction intersecting the one direction.

In an embodiment, the read-out line includes a first line and a second line spaced apart from the first line with the transmission area interposed therebetween, and the first line is electrically connected to the second line via the connection line.

In an embodiment, the connection line extends along one side of the transmission area.

In an embodiment, the connection line has a closed-line shape surrounding the transmission area.

In an embodiment, each of the light emitting elements includes a first electrode, a second electrode disposed on the first electrode, and a light emitting layer disposed between the first electrode and the second electrode. Each of the light receiving element includes a sensing anode electrode disposed on the same layer as the first electrode, a sensing cathode electrode disposed on the sensing anode electrode, and a photoelectric conversion layer disposed between the sensing anode electrode and the sensing cathode electrode.

According to embodiments of the present disclosure, as the signal line of the display panel is placed to detour the transmission area, the light transmittance of the transmission area is increased, and the optical sensor is disposed in the transmission area with increased light transmittance to receive an optical signal.

According to embodiments of the present disclosure, as the signal line of the display panel is placed along the periphery of the transmission area, a metal material with low resistance is used as the signal line, and thus, the light transmittance of the transmission area is increased while reducing a resistance of the signal line.

### BRIEF DESCRIPTION OF THE DRAWINGS

The above and other features of the present disclosure will become more apparent by describing in detail embodiments thereof with reference to the accompanying drawings, in which:

FIG. 1 is a perspective view of an electronic device according to an embodiment of the present disclosure;

FIG. 2 is an exploded perspective view of an electronic device according to an embodiment of the present disclosure;

FIG. 3 is a block diagram of an electronic device according to an embodiment of the present disclosure;

FIG. 4 is an enlarged plan view of a display panel corresponding to an area AA′ of FIG. 2 according to an embodiment of the present disclosure;

FIG. 5 is an equivalent circuit diagram of a pixel and a sensor according to an embodiment of the present disclosure;

FIG. 6 is a cross-sectional view of a display panel according to an embodiment of the present disclosure;

FIGS. 7A and 7B are cross-sectional views of an electronic device according to an embodiment of the present disclosure;

FIG. 8 is a cross-sectional view of an electronic device according to an embodiment of the present disclosure; and

FIGS. 9A to 9J are plan views of patterns forming a pixel and a sensor according to an embodiment of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure.

As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

It should be understood that descriptions of features or aspects within each embodiment should typically be considered as available for other similar features or aspects in other embodiments, unless the context clearly indicates otherwise.

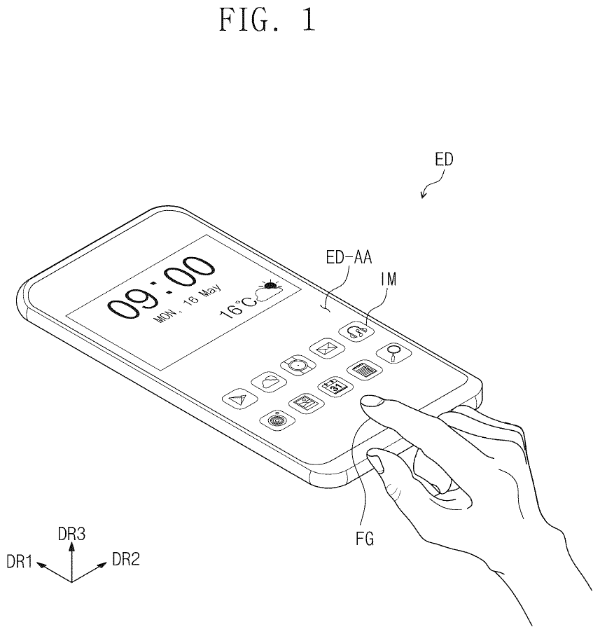

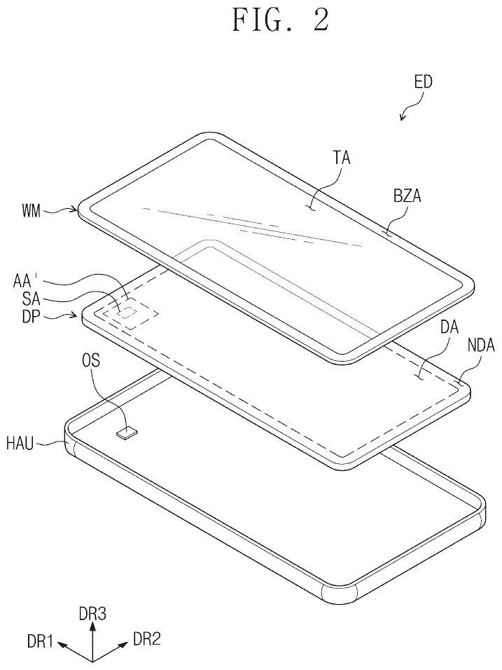

FIG. 1 is a perspective view of an electronic device ED according to an embodiment of the present disclosure. FIG. 2 is an exploded perspective view of the electronic device ED according to an embodiment of the present disclosure.

The electronic device ED may be activated in response to electrical signals and may display an image IM. As an example, the electronic device ED may be applied to a large-sized electronic product, such as a television set, an outdoor billboard, etc., and a small and medium-sized electronic item, such as a monitor, a mobile phone, a tablet computer, a navigation unit, a game unit, etc. However, these are merely examples, and the electronic device ED may be applied to other electronic devices as long as they do not depart from the concept of the present disclosure. In an embodiment described herein, the mobile phone is shown as an example of the electronic device ED.

Referring to FIG. 1, the electronic device ED may have a rectangular shape defined by long sides extending in a first direction DR1 and short sides extending in a second direction DR2 crossing the first direction DR1. However, the shape of the electronic device ED is not limited to the rectangular shape, and the electronic device ED may have a variety of shapes, such as, for example, a circular shape and a polygonal shape when viewed in a plane.

In an embodiment, a third direction DR3 may be substantially perpendicular to a plane defined by the first direction DR1 and the second direction DR2. Front (or upper) and rear (or lower) surfaces of each member of the electronic device ED may be disposed opposite to each other in the third direction DR3, and a normal line direction of each of the front and rear surfaces may be substantially parallel to the third direction DR3. A separation distance between the front and rear surfaces of each member (or each unit) in the third direction DR3 may correspond to a thickness in the member (or the unit) in the third direction DR3.

In the present disclosure, the expression “when viewed in a plane” may mean a state of being viewed in the third direction DR3. In the present disclosure, the expression “on a cross-section”, “in a cross-section”, or “in a cross-sectional view” may mean a state of being viewed in the first direction DR1 or the second direction DR2. Directions indicated by the first, second, and third directions DR1, DR2, and DR3 are relative to each other, and thus, the directions indicated by the first, second, and third directions DR1, DR2, and DR3 may be changed to other directions.

The electronic device ED according to embodiments of the present disclosure may be rigid or flexible. The term “flexible” used herein refers to the property of being able to be bent from a structure that is completely bent to a structure that is bent at the scale of a few nanometers. For example, the electronic device ED may be a curved electronic device or a foldable electronic device.

The electronic device ED may display the image IM through a display surface ED-AA. The display surface ED-AA may correspond to a front surface of the electronic device ED. The display surface ED-AA of the electronic device ED may be substantially parallel to the plane defined by the first direction DR1 and the second direction DR2 and may display the image IM in the third direction DR3 intersecting the plane. FIG. 1 shows a flat display surface ED-AA as a representative example. However, the shape of the display surface ED-AA is not limited thereto, and the display surface ED-AA may further include a curved surface bent from at least one side of the plane.

The image IM displayed through the electronic device ED may include a still image as well as a video. FIG. 1 shows a clock widget and application icons as a representative example of the image IM.

According to an embodiment, the electronic device ED may sense an external input applied thereto from the outside of the electronic device ED. The external input may include a variety of external inputs. As an example, the external input may include force, pressure, temperature, light, etc. The external input may include a proximity input (e.g., a hovering input) applied when approaching close to or adjacent to the electronic device ED at a predetermined distance (without physical contact being made) as well as a touch input, e.g., a touch by a hand of a user or a pen.

The electronic device ED may sense a user input via the display surface ED-AA defined in the front surface and may respond to the sensed input signal. However, an area of the electronic device ED in which the external input is sensed is not limited to the front surface of the electronic device ED and may be changed depending on a design of the electronic device ED. As an example, the electronic device ED may sense the user input applied to a side surface or a rear surface of the electronic device ED.

The electronic device ED may sense biometric information of the user, which is applied thereto from the outside of the electronic device ED. As an example, the electronic device ED may sense biometric information such as a fingerprint FG of the user. The electronic device ED may include a sensing area defined in the display surface ED-AA in which the biometric information of the user is sensed. The sensing area may be defined in an entire portion of the display surface ED-AA or may be defined in a portion less than the entirety of the display surface ED-AA. In an embodiment, the entire portion of the display surface ED-AA is used as the sensing area as a representative example.

Referring to FIG. 2, the electronic device ED may include a window WM, a display panel DP, and a housing HAU. The window WM may be coupled to the housing HAU to form an appearance of the electronic device ED and may provide an inner space to accommodate components of the electronic device ED.

The window WM may be disposed on the display panel DP. The window WM may have a shape corresponding to a shape of the display panel DP and may cover a front surface of the display panel DP. The window WM may protect the display panel DP from external impact and scratches.

The window WM may include an optically transparent insulating material. As an example, the window WM may include a glass or plastic material. The window WM may have a single-layer or multi-layer structure. As an example, the window WM may include a plurality of plastic films coupled to each other by an adhesive or a glass substrate and a plastic film coupled to the glass substrate by an adhesive. The window WM may further include functional layers, such as, for example, an anti-fingerprint layer, a phase control layer, a hard coating layer, etc., disposed on a transparent substrate.

A front surface of the window WM may correspond to the front surface of the electronic device ED. The front surface of the window WM may include a transmission portion TA and a bezel portion BZA.

The transmission portion TA may be an optically transparent area. The transmission portion TA may transmit the image IM provided from the display panel DP. The transmission portion TA may correspond to the display surface ED-AA of the electronic device ED, and the user may view the image IM through the transmission portion TA. In an embodiment, the transmission portion TA may have a quadrangular shape with rounded vertices. However, this is merely an example, and the transmission portion TA may have a variety of shapes according to embodiments.

The bezel portion BZA may be disposed adjacent to the transmission portion TA. The shape of the transmission portion TA may be defined by the bezel portion BZA. As an example, the bezel portion BZA may be disposed outside of the transmission portion TA and may surround the transmission portion TA, however, this is merely an example. According to an embodiment, the bezel portion BZA may be disposed adjacent to only one side of the transmission portion TA or may be omitted. According to an embodiment, the bezel portion BZA may be disposed on the side surface rather than the front surface of the electronic device ED.

The bezel portion BZA may have a light transmittance lower than a light transmittance of the transmission portion TA. The bezel portion BZA may be obtained by printing a material having a predetermined color. The bezel portion BZA may prevent a light from transmitting therethrough and may prevent components of the display panel DP, which overlap the bezel portion BZA, from being viewed from the outside of the electronic device ED.

The display panel DP may be disposed between the window WM and the housing HAU. The display panel DP may display the image IM in response to electrical signals. The display panel DP according to an embodiment of the present disclosure may be a light-emitting type display panel, however, is not limited thereto. For example, the display panel DP may be an organic light emitting display panel, an inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot or a quantum rod. Hereinafter, the organic light emitting display panel will be described as a representative example of the display panel DP.

According to an embodiment, the display panel DP may further include an input sensor. The input sensor may sense the external input and may obtain coordinate information of the external input. The input sensor may provide an input signal including information about the external input to allow the display panel DP to generate the image IM corresponding to the external input. The input sensor may be driven in various ways, such as, for example, a capacitive method, a resistive method, an infrared ray method, a sonic method, a pressure method, or the like, however, is not limited thereto.

The front surface of the display panel DP may include a display area DA and a non-display area NDA. The display area DA may be activated in response to electrical signals to display the image IM. The display area DA may overlap at least a portion of the transmission portion TA.

The display area DA may be an area in which a light emitting element and a light receiving element are disposed. The light emitting element may generate a light in response to an electrical signal. As an example, the light emitting element may be a light emitting diode. The light receiving element may sense the light incident to the light receiving element and may convert a light signal to an electrical signal. As an example, the light receiving element may be a photodiode. The display area DA may display the image through the light emitting element and may recognize the biometric information such as the fingerprint FG of the user through the light receiving element.

A transmission area SA may be defined in the display area DA. The display area DA may be disposed adjacent to the transmission area SA. For example, the display area DA may surround at least a portion of the transmission area SA. However, embodiments are not limited thereto. According to an embodiment, the transmission area SA may be disposed between the non-display area NDA and the display area DA, and a portion of the transmission area SA may be surrounded by the display area DA. According to an embodiment, the transmission area SA may be provided in plural, the transmission areas SA may be spaced apart from each other, and the transmission areas SA may be surrounded by the display area DA.

The transmission area SA may be an area with a relatively high light transmittance in the display area DA. The transmission area SA may be an area in which the light emitting element and the light receiving element are not disposed. This will be described in further detail below.

The non-display area NDA may be disposed adjacent to the display area DA. As an example, the non-display area NDA may surround the display area DA, however, it is not limited thereto. According to an embodiment, the non-display area NDA may be defined in a variety of shapes. A driving circuit or a driving line that drives elements disposed in the display area DA, various signal lines that provide electrical signals, and pads may be disposed in the non-display area NDA. The non-display area NDA may overlap at least a portion of the bezel portion BZA, and components disposed in the non-display area NDA may be prevented from being viewed from the outside by the bezel portion BZA.

An optical sensor OS may receive a light signal provided from the outside of the electronic device ED and may sense information about an external environment. As an example, the optical sensor OS may be an illumination sensor, an optical sensor, or a proximity sensor. The illumination sensor may measure a level of an ambient light to control a brightness of a screen of the display area DA. The optical sensor may measure an intensity of the ambient light to correct a color of the display area DA. The proximity sensor may measure a distance from a specific body part or a specific object by using the light signal to control the display area DA when the specific body part or the specific object approaches.

The optical sensor OS may be accommodated in the inner space provided by the housing HAU and may be disposed under the display panel DP. The optical sensor OS may overlap the transmission area SA of the display panel DP. The optical sensor OS may receive the light signal exiting from the transmission area SA or may output the light signal through the transmission area SA. Accordingly, a sensitivity or reliability of the optical sensor OS may vary depending on the light transmittance of the transmission area SA. The display panel DP may provide the transmission area SA with increased light transmittance without affecting the drive of the elements, and thus, the reliability of the display panel DP and the optical sensor OS may be increased.

The housing HAU may be disposed under the display panel DP and may accommodate the display panel DP. The housing HAU may include a material with a relatively high rigidity. For example, the housing HAU may include a glass, plastic, or metal material or a plurality of frames and/or plates of combinations thereof. The housing HAU may absorb external impact applied thereto from the outside of the electronic device ED, which may reliably protect the display panel DP and may prevent a foreign substance or moisture from entering the display panel DP.

The electronic device ED may further include a variety of functional electronic modules that drive the display panel DP and the optical sensor OS, a power supply module that supplies a power utilized for an overall operation of the electronic device ED, and a bracket coupled to the display panel DP or the housing HAU that divides an inner space of the electronic device ED.

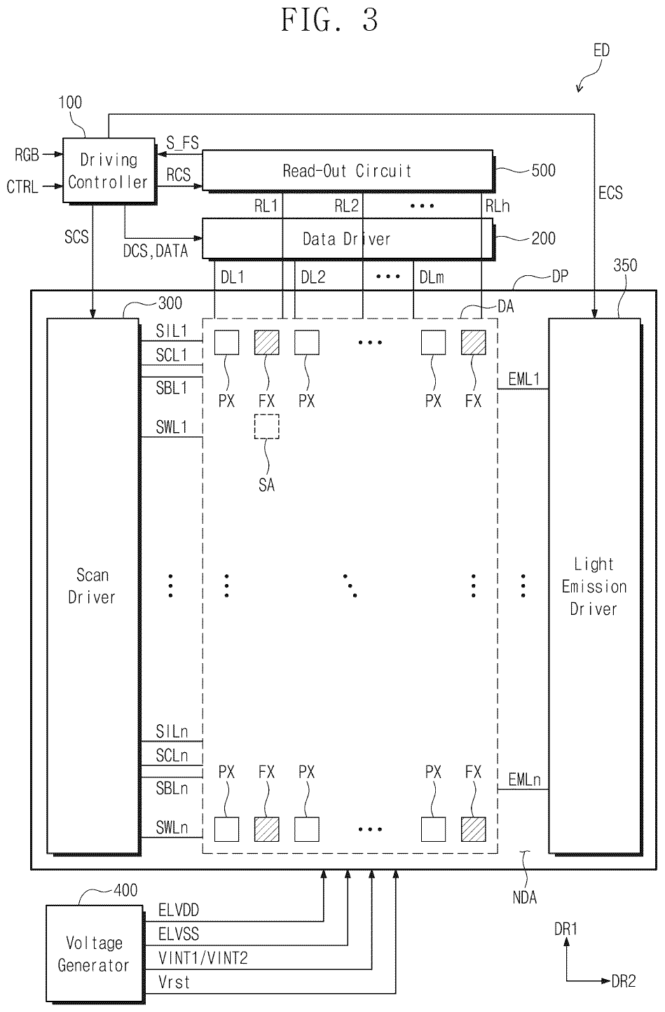

FIG. 3 is a block diagram of the electronic device ED according to an embodiment of the present disclosure.

Referring to FIG. 3, the electronic device ED may include the display panel DP, a driving controller 100, a data driver 200, a scan driver 300, a light emission driver 350, a voltage generator 400, and a read-out circuit 500.

The driving controller 100 may receive an image signal RGB and control signals CTRL. The driving controller 100 may convert a data format of the image signal RGB to a data format appropriate for an interface between the data driver 200 and the driving controller 100 to generate an image data signal DATA. The driving controller 100 may generate a first control signal SCS, a second control signal ECS, a third control signal DCS, and a fourth control signal RCS.

The data driver 200 may receive the third control signal DCS and the image data signal DATA from the driving controller 100. The data driver 200 may convert the image data signal DATA to data signals and may output the data signals to a plurality of data lines DL1 to DLm, where m is a positive integer, as described further below. The data signals may be analog voltages corresponding to grayscale values of the image data signal DATA.

The scan driver 300 may receive the first control signal SCS from the driving controller 100. The scan driver 300 may output scan signals to scan lines SILn, SCLn, SBLn, and SWLn, where n is a positive integer, in response to the first control signal SCS. The scan signals SILn, SCLn, SBLn, and SWLn may include initialization scan lines SIL1 to SILn, compensation scan lines SCL1 to SCLn, write scan lines SWL1 to SWLn, and black scan lines SBL1 to SBLn.

The light emission driver 350 may receive the second control signal ECS from the driving controller 100. The light emission driver 350 may output light emission control signals to light emission control lines EML1 to EMLn in response to the second control signal ECS.

The voltage generator 400 may generate voltages utilized to operate the display panel DP. In an embodiment, the voltage generator 400 may generate a first driving voltage ELVDD, a second driving voltage ELVSS, a first initialization voltage VINT1, a second initialization voltage VINT2, and a reset voltage Vrst. However, the voltage generated by the voltage generator 400 is not limited thereto.

The display panel DP may include a plurality of pixels PX disposed in the display area DA and a plurality of sensors FX disposed in the display area DA. As an example, each of the sensors FX may be disposed between two pixels PX disposed adjacent to each other. The pixels PX and the sensors FX may be alternately arranged with each other in the first and second directions DR1 and DR2, however, the present disclosure is not limited thereto. As an example, two or more pixels PX may be disposed between two sensors FX disposed adjacent to each other in the first direction DR1 among the sensors FX, or two or more pixels PX may be disposed between two sensors FX disposed adjacent to each other in the second direction DR2 among the sensors FX.

The display panel DP may include the transmission area SA defined in the display area DA. The transmission area SA may be an area in which the pixels PX and the sensors FX of the display panel DP are not disposed. The transmission area SA may have a light transmittance higher than that of the display area DA in which the pixels PX and the sensors FX are disposed. The transmission area SA may overlap the optical sensor OS (refer to FIG. 2).

The initialization scan lines SIL1 to SILn, the compensation scan lines SCL1 to SCLn, the write scan lines SWL1 to SWLn, the black scan lines SBL1 to SBLn, and the light emission control lines EML1 to EMLn may extend in the second direction DR2 and may be arranged spaced apart from each other in the first direction DR1. The data lines DL1 to DLm and read-out lines RL1 to RLh, where h is a positive integer, may extend in the first direction DR1 and may be arranged spaced apart from each other in the second direction DR2.

The pixels PX may be electrically connected to the initialization scan lines SIL1 to SILn, the compensation scan lines SCL1 to SCLn, the write scan lines SWL1 to SWLn, the black scan lines SBL1 to SBLn, the light emission control lines EML1 to EMLn, and the data lines DL1 to DLm. Each of the pixels PX may be electrically connected to four scan lines, however, the present disclosure is not limited thereto. The number of the scan lines connected to each of the pixels PX may be changed.

The sensors FX may be electrically connected to the write scan lines SWL1 to SWLn and the read-out lines RL1 to RLh. Each of the sensors FX may be electrically connected to one scan line, however, the present disclosure is not limited thereto. The number of the scan lines connected to each of the sensors FX may be changed. As an example, the number of the read-out lines RL1 to RLh may be equal to or smaller than the number of the data lines DL1 to DLm. As an example, the number of the read-out lines RL1 to RLh may correspond to ½, ¼, or ⅛ of the number of the data lines DL1 to DLm.

The scan driver 300 may be disposed in the non-display area NDA of the display panel DP. The scan driver 300 may receive the first control signal SCS from the driving controller 100. Responsive to the first control signal SCS, the scan driver 300 may output initialization scan signals to the initialization scan lines SIL1 to SILn and may output compensation scan signals to the compensation scan lines SCL1 to SCLn. In addition, responsive to the first control signal SCS, the scan driver 300 may output write scan signals to the write scan lines SWL1 to SWLn and may output black scan signals to the black scan lines SBL1 to SBLn. According to an embodiment, the scan driver 300 may include a first scan driver that outputs the initialization scan signals and the compensation scan signals and a second scan driver that outputs the write scan signals and the black scan signals, however, the present disclosure is not limited thereto.

The light emission driver 350 may be disposed in the non-display area NDA of the display panel DP. The light emission driver 350 may receive the second control signal ECS from the driving controller 100. The light emission driver 350 may output the light emission control signals to the light emission control lines EML1 to EMLn in response to the second control signal ECS. In an embodiment, the scan driver 300 and the light emission driver 350 are shown as being separated from each other, however, the present disclosure is not limited thereto. According to an embodiment, the scan driver 300 may be connected to the light emission control lines EML1 to EMLn and may output the light emission control signals, and the light emission driver 350 may be omitted.

The read-out circuit 500 may receive sensing signals from the read-out lines RL1 to RLh in response to the fourth control signal RCS received from the driving controller 100. The read-out circuit 500 may process the sensing signals from the read-out lines RL1 to RLh and may provide the processed sensing signals S_FS to the driving controller 100. The driving controller 100 may sense the biometric information based on the sensing signals S_FS.

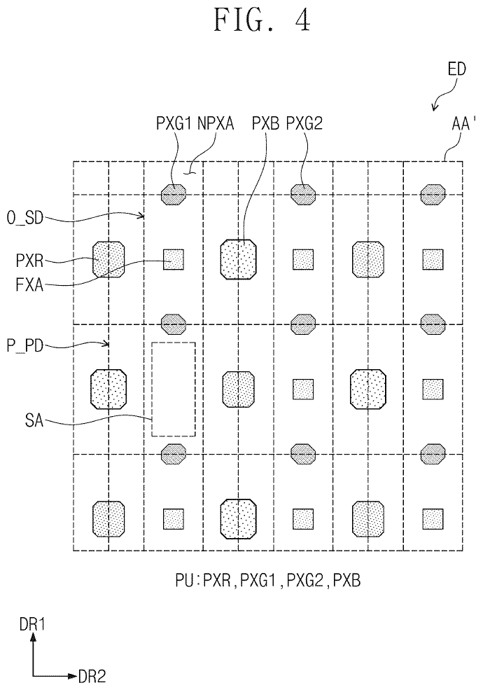

FIG. 4 is an enlarged plan view of the display panel corresponding to an area AA′ of FIG. 2 according to an embodiment of the present disclosure. The area AA′ shown in FIG. 4 may correspond to a portion of the display area DA including the transmission area SA.

The display area DA may include pixel areas PXR, PXG1, PXG2, and PXB, light receiving areas FXA, and a peripheral area NPXA. The peripheral area NPXA may surround the pixel areas PXR, PXG1, PXG2, and PXB and the light receiving areas FXA and may define a boundary between the pixel areas PXR, PXG1, PXG2, and PXB and the light receiving areas FXA. A portion of the peripheral area NPXA may correspond to the transmission area SA. The transmission area SA may have a relatively high light transmittance in the peripheral area NPXA.

The pixel areas PXR, PXG1, PXG2, and PXB may correspond to areas in which the light emitting elements are disposed. The light receiving areas FXA may correspond to areas in which the light receiving elements are disposed. The pixel areas PXR, PXG1, PXG2, and PXB may include first pixel areas PXR, second pixel areas PXG1 and PXG2, and third pixel areas PXB. The first to third pixel areas PXR, PXG1, PXG2, and PXB may be distinguished from each other according to colors of light emitted therefrom. As an example, each of the first pixel areas PXR may emit a first color light, each of the second pixel areas PXG1 and PXG2 may emit a second color light different from the first color light, and each of the third pixel areas PXB may emit a third color light different from the first and second color lights. As an example, the first, second, and third color lights may be respectively a red light, a green light, and a blue light, however, the present disclosure is not limited thereto.

The pixel areas PXR, PXG1, PXG2, and PXB may be grouped in a pixel unit PU. As an example, the pixel unit PU may include one first pixel area PXR, two second pixel areas PXG1 and PXG2, and one third pixel area PXB. However, the number of the pixel areas forming the pixel unit PU is not limited thereto.

The first pixel areas PXR may be alternately arranged with the third pixel areas PXB in the first direction DR1 and the second direction DR2. The second pixel areas PXG1 and PXG2 may be arranged in the first direction DR1 and the second direction DR2. The second pixel areas PXG1 and PXG2 may be arranged in a different row and a different column from those of the first pixel areas PXR and the third pixel areas PXB in the first direction DR1 and the second direction DR2.

Each of the second pixel areas PXG1 and PXG2 may have a size smaller than that of each of the first pixel area PXR and the third pixel area PXB. The first pixel area PXR may have a size smaller than that of the third pixel area PXB, however, the present disclosure is not limited thereto. According to an embodiment, the first pixel area PXR and the third pixel area PXB may have substantially the same size as each other or all the first to third pixel areas PXR, PXG1, PXG2, and PXB may have substantially the same size as each other.

The first to third pixel areas PXR, PXG1, PXG2, and PXB may have different shapes from each other. As an example, the first pixel area PXR and the third pixel area PXB may have an octagonal shape extending in the first direction DR1, and the second pixel areas PXG1 and PXG2 may have an octagonal shape extending in the second direction DR2 different from the direction in which the first pixel area PXR extends. Some of the second pixel areas PXG1 and PXG2 may have shapes that are symmetrical to each other. However, the shapes of the first to third pixel areas PXR, PXG1, PXG2, and PXB are not limited thereto and may have a variety of shapes, such as, for example, an oval shape, a circular shape, a quadrangular shape, or the like.

The light receiving areas FXA may be arranged in the first direction DR1 and the second direction DR2. The light receiving areas FXA may be disposed between the second pixel areas PXG1 and PXG2 in the first direction DR1 and may be disposed between the first pixel area PXR and the third pixel area PXB in the second direction DR2.

Each of the light receiving areas FXA may have the quadrangular shape when viewed in the plane. Each of the light receiving areas FXA may have a size smaller than that of each of the first to third pixel areas PXR, PXG1, PXG2, and PXB, however, the present disclosure is not limited thereto.

The first to third pixel areas PXR, PXG1, PXG2, and PXB and the light receiving area FXA may be spaced apart from the transmission area SA. That is, in an embodiment, the light emitting elements and the light receiving elements are not disposed in the transmission area SA. Accordingly, the transmission area SA may have a relatively high light transmittance in the display area DA.

A pixel driving circuit P_PD electrically connected to the light emitting element and a sensor driving circuit O_SD electrically connected to the light receiving element may be disposed in the area AA′ corresponding to the display area DA. The pixel driving circuit P_PD may be disposed adjacent to the light emitting element, and the sensor driving circuit O_SD may be disposed adjacent to the light receiving element. The pixel driving circuit P_PD and the sensor driving circuit O_SD may be arranged in a specific rule when viewed in the plane, and this will be described in further detail below.

The transmission area SA may be spaced apart from the pixel driving circuit P_PD and the sensor driving circuit O_SD. That is, in an embodiment, components of the pixel driving circuit P_PD and the sensor driving circuit O_SD are not disposed in the transmission area SA. Therefore, the transmission area SA may have a relatively high light transmittance in the display area DA.

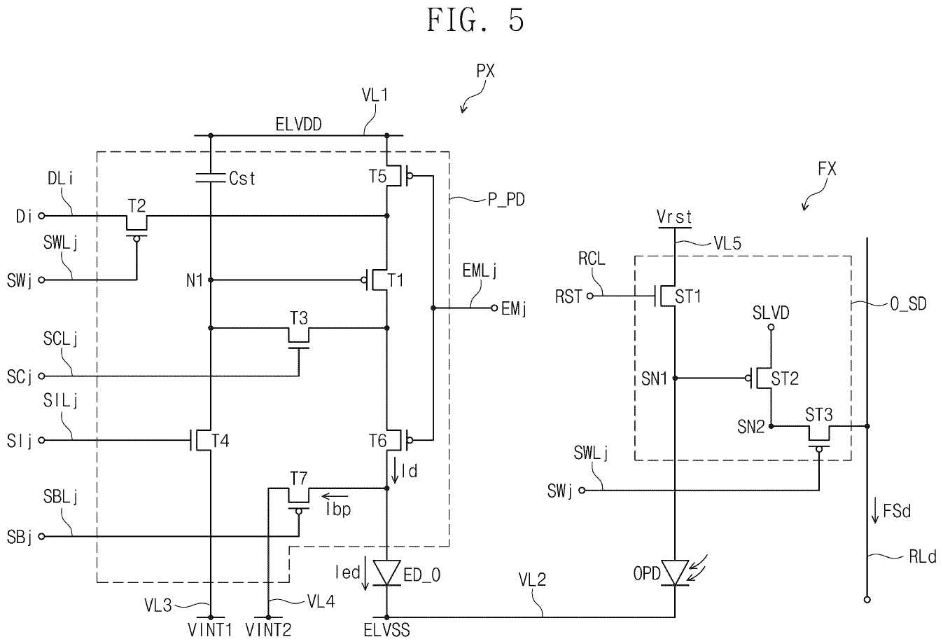

FIG. 5 shows an equivalent circuit diagram of one pixel PX and one sensor FX among the pixels PX and the sensors FX shown in FIG. 3. Descriptions of the equivalent circuit diagram of the one pixel PX may be applied to other pixels PX, and descriptions of the equivalent circuit diagram of the one sensor FX may be applied to other sensors FX.

Referring to FIG. 5, the pixel PX may be connected to an i-th data line DLi among the data lines DL1 to DLm, a j-th initialization scan line SILj among the initialization scan lines SIL1 to SILn, a j-th compensation scan line SCLj among the compensation scan lines SCL1 to SCLn, a j-th write scan line SWLj among the write scan lines SWL1 to SWLn, a j-th black scan line SBLj among the black scan lines SBL1 to SBLn, and a j-th light emission control line EMLj among the light emission control lines EML1 to EMLn, where each of i, j, m, and n is a positive integer.

The pixel PX may include the light emitting element ED_O and the pixel driving circuit P_PD. The light emitting element ED_O may be a light emitting diode. As an example, the light emitting element ED_O may be an organic light emitting diode including an organic light emitting layer. The pixel driving circuit P_PD may be connected to the light emitting element ED_O and may control an amount of current flowing through the light emitting element ED_O, and the light emitting element ED_O may generate a light with a predetermined brightness according to the amount of current.

The pixel driving circuit P_PD may include first, second, third, fourth, fifth, sixth, and seventh transistors T1, T2, T3, T4, T5, T6, and T7 and a capacitor Cst. Each of the first to seventh transistors T1 to T7 may be a transistor including a low-temperature polycrystalline silicon (LTPS) semiconductor layer or a transistor including an oxide semiconductor layer. Each of the first to seventh transistors T1 to T7 may be a P-type transistor or an N-type transistor. As an example, each of the first, second, fifth, sixth, and seventh transistors T1, T2, T5, T6, and T7 may be a PMOS transistor including the LTPS semiconductor layer, and each of the third and fourth transistors T3 and T4 may be an NMOS transistor including the oxide semiconductor layer. However, these are merely examples, and the first to seventh transistors T1 to T7 are not limited thereto.

The j-th initialization scan line SILj, the j-th compensation scan line SCLj, the j-th write scan line SWLj, the j-th black scan line SBLj, and the j-th light emission control line EMLj may transmit a j-th initialization scan signal SIj, a j-th compensation scan signal SCj, a j-th write scan signal SWj, a j-th black scan signal SBj, and a j-th light emission control signal EMj to the pixel PX, respectively. The i-th data line DLi may transmit an i-th data signal Di to the pixel PX. The i-th data signal Di may have a voltage level corresponding to the image signal RGB (refer to FIG. 3) input to the electronic device ED (refer to FIG. 3).

First and second voltage lines VL1 and VL2 may respectively transmit the first driving voltage ELVDD and the second driving voltage ELVSS to the pixel PX. In addition, third and fourth voltage lines VL3 and VL4 may respectively transmit the first initialization voltage VINT1 and the second initialization voltage VINT2 to the pixel PX.

The light emitting element ED_O may include a first electrode and a second electrode. The first electrode of the light emitting element ED_O may be electrically connected to the first voltage line VL1 that receives the first driving voltage ELVDD via at least one transistor. The second electrode of the light emitting element ED_O may be electrically connected to the second voltage line VL2 that receives the second driving voltage ELVSS. According to an embodiment, the first electrode of the light emitting element ED_O may correspond to an anode electrode, and the second electrode of the light emitting element ED_O may correspond to a cathode electrode.

Each of the first to seventh transistors T1 to T7 may include a first electrode, a second electrode, and a gate electrode. According to an embodiment, the first electrode and the second electrode may be respectively defined as an input electrode and an output electrode (or a source electrode and a drain electrode). In the present disclosure, the expression “a transistor and a signal line or a transistor and another transistor are electrically connected” may mean that an electrode of the transistor is integrally provided with the signal line or that the electrode of the transistor and the signal line are connected through a connection electrode.

The first transistor T1 may be electrically connected between the first voltage line VL1 that receives the first driving voltage ELVDD and the light emitting element ED_O. The first transistor T1 may include the first electrode connected to the first voltage line VL1 via the fifth transistor T5, the second electrode connected to the first electrode of the light emitting element ED_O via the sixth transistor T6, and the gate electrode connected to one end of the capacitor Cst. The first transistor T1 may receive the i-th data signal Di provided through the i-th data line DLi according to a switching operation of the second transistor T2 and may provide a driving current Id to the light emitting element ED_O. In an embodiment, the first transistor T1 may be defined as a driving transistor.

The second transistor T2 may be connected between the i-th data line DLi and the first electrode of the first transistor T1. The second transistor T2 may include the first electrode connected to the i-th data line DLi, the second electrode connected to the first electrode of the first transistor T1, and the gate electrode connected to the j-th write scan line SWLj. The second transistor T2 may be turned on in response to the j-th write scan signal SWj applied thereto through the j-th write scan line SWLj and may transmit the i-th data signal Di provided from the i-th data line DLi to the first electrode of the first transistor T1. In an embodiment, the second transistor T2 may be defined as a switching transistor.

The third transistor T3 may be electrically connected between the second electrode of the first transistor T1 and a first node N1 connected to the gate electrode of the first transistor T1. The third transistor T3 may include the first electrode connected to the first node N1, the second electrode connected to the second electrode of the first transistor T1, and the gate electrode connected to the j-th compensation scan line SCLj. The third transistor T3 may be turned on in response to the j-th compensation scan signal SCj applied thereto through the j-th compensation scan line SCLj and may connect the second electrode and the gate electrode of the first transistor T1, and thus, the first transistor T1 may be connected in a diode configuration. In an embodiment, the third transistor T3 may be defined as a compensation transistor.

The fourth transistor T4 may be electrically connected between the third voltage line VL3 to which the first initialization voltage VINT1 is applied and the first node N1. The fourth transistor T4 may include the first electrode connected to the third voltage line VL3, the second electrode connected to the first node N1, and the gate electrode connected to the j-th initialization scan line SILj. The fourth transistor T4 may be turned on in response to the j-th initialization scan signal SIj applied thereto through the j-th initialization scan line SILj. The turned-on fourth transistor T4 may supply the first initialization voltage VINT1 to the first node N1 to initialize an electric potential of the gate electrode of the first transistor T1. In an embodiment, the fourth transistor T4 may be defined as an initialization transistor.

The fifth transistor T5 may be electrically connected between the first voltage line VL1 and the first transistor T1. The fifth transistor T5 may include the first electrode connected to the first voltage line VL1, the second electrode connected to the first electrode of the first transistor T1, and the gate electrode connected to the j-th light emission control line EMLj.

The sixth transistor T6 may be electrically connected between the first transistor T1 and the light emitting element ED_O. The sixth transistor T6 may include the first electrode connected to the second electrode of the first transistor T1, the second electrode connected to the first electrode of the light emitting element ED_O, and the gate electrode connected to the j-th light emission control line EMLj.

The fifth transistor T5 and the sixth transistor T6 may be turned on in response to the j-th light emission control signal EMj applied thereto through the j-th light emission control line EMLj. A light emission time of the light emitting element ED_O may be controlled by the j-th light emission control signal EMj. When the fifth transistor T5 and the sixth transistor T6 are turned on, the driving current Id may be generated according to a voltage difference between a gate voltage of the gate electrode of the first transistor T1 and the first driving voltage ELVDD, the driving current Id may be supplied to the light emitting element ED_O via the sixth transistor T6, and thus, the light emitting element ED_O may emit the light. In an embodiment, the fifth transistor T5 and the sixth transistor T6 may be defined as a light emission control transistor.

The seventh transistor T7 may be electrically connected between the fourth voltage line VL4 to which the second initialization voltage VINT2 is applied and the sixth transistor T6. The seventh transistor T7 may include the first electrode connected to the fourth voltage line VL4, the second electrode connected to the second electrode of the sixth transistor T6, and the gate electrode connected to the j-th black scan line SBLj. In an embodiment, the seventh transistor T7 may be defined as an initialization transistor.

The seventh transistor T7 may be turned on in response to the j-th black scan signal SBj applied thereto through the j-th black scan line SBLj. A portion of the driving current Id may be bypassed as a bypass current Ibp via the seventh transistor T7. In a case in which a black image is displayed, a current, e.g., a light emitting current Ied, reduced by an amount of the bypass current Ibp, which is bypassed through the seventh transistor T7, from the driving current Id may be provided to the light emitting element ED_O, and thus, the black image may be clearly displayed. That is, the pixel PX may display an accurate black grayscale image using the seventh transistor T7, and as a result, a contrast ratio of the electronic device ED (refer to FIG. 1) may be improved. According to an embodiment, the seventh transistor T7 may be turned on in response to the j-th black scan signal SBj with a low level as the bypass signal, however, the present disclosure is not limited thereto.

The one end of the capacitor Cst may be connected to the gate electrode of the first transistor T1, and the other end of the capacitor Cst may be connected to the first voltage line VL1. The capacitor Cst may be charged with electric charges corresponding to a difference in voltage between the one end and the other end of the capacitor Cst. When the fifth transistor T5 and the sixth transistor T6 are turned on, the amount of current flowing through the first transistor T1 may be determined according to the voltage charged in the capacitor Cst.

The configuration of the pixel driving circuit P_PD shown in FIG. 5 is merely an example, and the configuration of the pixel driving circuit P_PD may be changed without being limited to the configuration shown in FIG. 5.

Referring to FIG. 5, the sensor FX may be connected to a d-th read-out line RLd among the read-out lines RL1 to RLh, the j-th write scan line SWLj, and a reset control line RCL, where d is a positive integer.

The sensor FX may include the light receiving element OPD and the sensor driving circuit O_SD connected to the light receiving element OPD. The light receiving element OPD may be a photodiode, and as an example, the light receiving element OPD may be an organic photodiode including an organic material as a photoelectric conversion layer. FIG. 5 shows one light receiving element OPD connected to the sensor driving circuit O_SD as a representative example, however, the present disclosure is not limited thereto. The sensor FX may include a plurality of light receiving elements connected in parallel to the sensor driving circuit O_SD.

The sensor driving circuit O_SD may include three transistors ST1, ST2, and ST3. The three transistors ST1, ST2, and ST3 may be a reset transistor ST1, an amplification transistor ST2, and an output transistor ST3, respectively. Each of the reset transistor ST1, the amplification transistor ST2, and the output transistor ST3 may be a transistor with an LTPS semiconductor layer or a transistor with an oxide semiconductor layer. In addition, each of the reset transistor ST1, the amplification transistor ST2, and the output transistor ST3 may be a P-type transistor or an N-type transistor. As an example, the reset transistor ST1 may be an NMOS transistor with the oxide semiconductor layer, and each of the amplification transistor ST2 and the output transistor ST3 may be a PMOS transistor with the LTPS semiconductor layer. However, these are merely examples, and the transistors ST1 to ST3 included in the sensor driving circuit O_SD are not limited thereto.

The reset control line RCL may receive a reset control signal RST and may transmit the reset control signal RST to the sensor FX, and a fifth voltage line VL5 may receive the reset voltage Vrst and may transmit the reset voltage Vrst to the sensor FX.

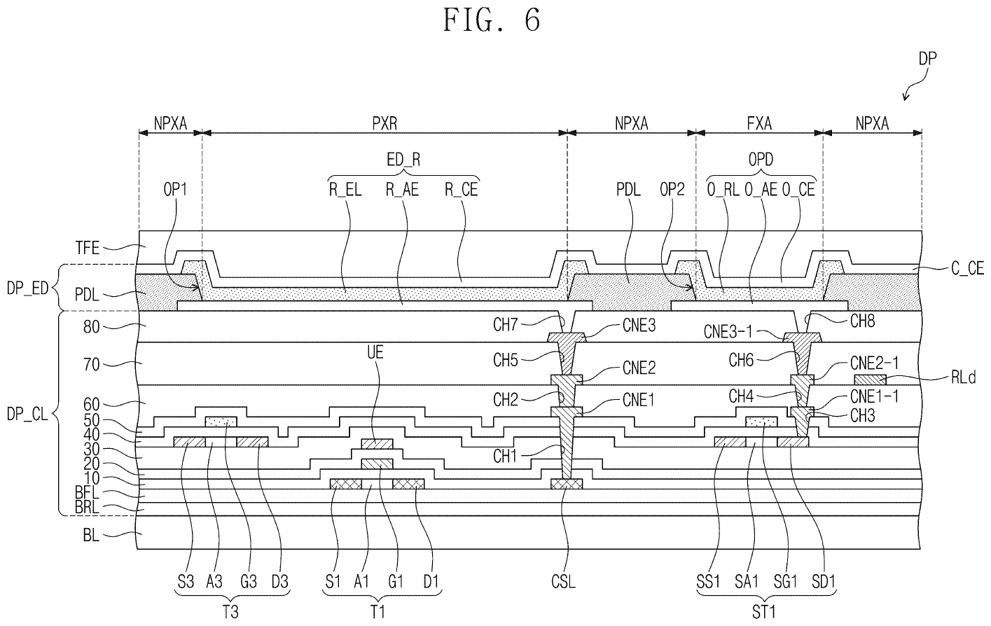

The light receiving element OPD may include a first electrode and a second electrode. The first electrode of the light receiving element OPD may be connected to a first sensing node SN1, and the second electrode of the light receiving element OPD may be connected to the second voltage line VL2 that receives the second driving voltage ELVSS. The second electrode of the light receiving element OPD may be electrically connected to the second electrode of the light emitting element ED_O. As an example, the second electrode of the light receiving element OPD may be formed integrally with the second electrode of the light emitting element ED_O, and thus, a common cathode electrode C_CE (refer to FIG. 6) may be formed. According to an embodiment, the first electrode of the light receiving element OPD may correspond to a sensing anode electrode, and the second electrode of the light receiving element OPD may correspond to a sensing cathode electrode.

Each of the transistors ST1 to ST3 of the sensor driving circuit O_SD may include a first electrode, a second electrode, and a gate electrode. According to an embodiment, the first electrode and the second electrode may be respectively defined as an input electrode and an output electrode or as a source electrode and a drain electrode.

The reset transistor ST1 may include the first electrode connected to the fifth voltage line VL5 receiving the reset voltage Vrst, the second electrode connected to the first sensing node SN1, and the gate electrode connected to the reset control line RCL that receives the reset control signal RST. The reset transistor ST1 may reset an electric potential of the first sensing node SN1 to the reset control signal RST in response to the reset control signal RST. The reset control signal RST may be a signal provided through the reset control line RCL, however, the present disclosure is not limited thereto. Alternatively, the reset control signal RST may be the j-th compensation scan signal SCj provided through the j-th compensation scan line SCLj. That is, the reset transistor ST1 may receive the j-th compensation scan signal SCj provided through the j-th compensation scan line SCLj as the reset control signal RST.

As an example, the reset voltage Vrst may have a voltage level lower than that of the second driving voltage ELVSS, at least during an activation period of the reset control signal RST. The reset voltage Vrst may be a DC voltage maintained at a voltage level lower than that of the second driving voltage ELVSS.

The amplification transistor ST2 may include the first electrode that receives a sensing driving voltage SLVD, the second electrode connected to a second sensing node SN2, and the gate electrode connected to the first sensing node SN1. The amplification transistor ST2 may be turned on depending on the electric potential of the first sensing node SN1 and may apply the sensing driving voltage SLVD to the second sensing node SN2.

The sensing driving voltage SLVD may be one of the first driving voltage ELVDD and the first and second initialization voltages VINT1 and VINT2. When the sensing driving voltage SLVD is the first driving voltage ELVDD, the first electrode of the amplification transistor ST2 may be electrically connected to the first voltage line VL1. When the sensing driving voltage SLVD is the first initialization voltage VINT1, the first electrode of the amplification transistor ST2 may be electrically connected to the third voltage line VL3, and when the sensing driving voltage SLVD is the second initialization voltage VINT2, the first electrode of the amplification transistor ST2 may be electrically connected to the fourth voltage line VL4.

The output transistor ST3 may include the first electrode connected to the second sensing node SN2, the second electrode connected to the d-th read-out line RLd, and the gate electrode receiving an output control signal. The output transistor ST3 may apply a sensing signal FSd to the d-th read-out line RLd in response to the output control signal. The output control signal may be the j-th write scan signal SWj provided through the j-th write scan line SWLj. That is, the output transistor ST3 may receive the j-th write scan signal SWj provided through the j-th write scan line SWLj as the output control signal.

The light receiving element OPD of the sensor FX may be exposed to a light emitted from the light emitting element ED_O during the light emitting period of the light emitting element ED_O. When a user's hand touches the display surface ED-AA (refer to FIG. 1), the light receiving element OPD may generate photo-charges corresponding to a light reflected by ridges of the user's fingerprint FG (refer to FIG. 1) or valleys between the ridges of the user's fingerprint FG. The amount of current flowing through the light receiving element may vary depending on the generated photo-charges.

The amplification transistor ST2 may be a source follower amplifier that generates a source-drain current in proportion to an electric charge of the first sensing node SN1 input to the gate electrode. When the output transistor ST3 is turned on in response to the j-th write scan signal SWj having the low level, the sensing signal FSd corresponding to a current flowing through the amplification transistor ST2 may be output to the d-th read-out line RLd.

Then, when the reset control signal RST having a high level is provided through the reset control line RCL during a reset period, the reset transistor ST1 may be turned on. The reset period may be defined as an activation period, e.g., a high level period, of the reset control line RCL. Alternatively, when the reset transistor ST1 is the PMOS transistor, the reset control signal RST having the low level may be applied to the reset control line RCL during the reset period. During the reset period, the first sensing node SN1 may be reset to an electric potential corresponding to the reset voltage Vrst, and when a next reset period is finished, the light receiving element OPD may generate photo-charges corresponding to the light provided thereto, and the generated photo-charges may be accumulated in the first sensing node SN1.

The configuration of the sensor driving circuit O_SD shown in FIG. 5 is merely an example, and the configuration of the sensor driving circuit O_SD may be changed without being limited to the configuration shown in FIG. 5.

FIG. 6 is a cross-sectional view of the display panel DP according to an embodiment of the present disclosure. FIG. 6 shows a cross-section of some components of the pixel PX (refer to FIG. 5) and the sensor FX (refer to FIG. 5) included in the display panel DP.

Referring to FIG. 6, the display panel DP may include a base layer BL, a circuit layer DP_CL, an element layer DP_ED, and an encapsulation layer TFE.

The base layer BL may provide a base surface on which the circuit layer DP-CL is disposed. The base layer BL may include a synthetic resin layer. The synthetic resin layer may include a heat-curable resin. The synthetic resin layer may include at least one of, for example, an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. According to an embodiment, the base layer BL may include, for example, a glass substrate, a metal substrate, or an organic/inorganic composite material substrate.

The circuit layer DP_CL may be disposed on the base layer BL. The circuit layer DP_CL may include the pixel driving circuit P_PD (refer to FIG. 5) included in the pixel PX (refer to FIG. 5) that displays the image and the sensor driving circuit O_SD (refer to FIG. 5) included in the sensor FX (refer to FIG. 5) that senses the biometric information. The circuit layer DP_CL may further include signal lines connected to the pixel driving circuit P_PD (refer to FIG. 5) or the sensor driving circuit O_SD (refer to FIG. 5).

The circuit layer DP_CL may include, for example, at least one insulating layer, a semiconductor pattern, and a conductive pattern, which form driving circuits. The insulating layer, a semiconductor layer, and a conductive layer may be formed on the base layer BL by, for example, a coating or depositing process. Then, the insulating layer, the semiconductor layer, and the conductive layer may be patterned through several photolithography processes, and thus, the semiconductor pattern and the conductive pattern may be formed.

The circuit layer DP_CL may include a barrier layer BRL and/or a buffer layer BFL. The barrier layer BRL may prevent a foreign substance from entering from the outside of the electronic device ED. The barrier layer BRL may include, for example, a silicon oxide layer and a silicon nitride layer. Each of the silicon oxide layer and the silicon nitride layer may be provided in plural, and the silicon oxide layers may be alternately stacked with the silicon nitride layers.

The buffer layer BFL may be disposed on the barrier layer BRL. The buffer layer BFL may increase an adhesion between the base layer BL and the semiconductor pattern and/or between the base layer BL and the conductive pattern. The buffer layer BFL may include, for example, a silicon oxide layer and a silicon nitride layer, which are alternately stacked on one another.

As shown in FIG. 6, the circuit layer DP_CL may include a first semiconductor pattern layer and a second semiconductor pattern layer, which are disposed on different layers from each other. However, the cross-section of the circuit layer DP_CL is not limited thereto and may be changed according to a configuration of the driving circuits.

The first semiconductor pattern layer of the circuit layer DP_CL may be disposed on the buffer layer BFL. As an example, the first semiconductor pattern layer may be disposed directly on the buffer layer BFL. The first semiconductor pattern layer may include, for example, a silicon semiconductor. The first semiconductor pattern layer may include, for example, polysilicon. However, the present disclosure is not limited thereto. According to an embodiment, the first semiconductor pattern layer may include amorphous silicon.

The first semiconductor pattern layer may include a plurality of regions having different electrical properties depending on whether the region(s) is doped and/or whether the region(s) is doped with an N-type dopant or a P-type dopant. The first semiconductor pattern layer may include a first region having a high conductivity and a second region having a low conductivity. The first region may be doped with the N-type dopant or the P-type dopant. A P-type transistor may include a doped region doped with the P-type dopant, and an N-type transistor may include a doped region doped with the N-type dopant. The second region may be a non-doped region or a region doped with a relatively low concentration compared with the first region.

The first region may have the conductivity greater than that of the second region and may substantially serve as a source electrode and a drain electrode of a transistor. The second region may substantially correspond to an active (or a channel) of the transistor. In other words, the first region of the first semiconductor pattern layer, which has the relatively high conductivity, may be the source or drain of the transistor or a connection signal line, and the second region of the first semiconductor pattern layer, which has the relatively low conductivity, may be the active of the transistor.

Referring to FIG. 6, a first source electrode S1, a first active A1, and a first drain electrode D1 of the first transistor T1 may be formed from the first semiconductor pattern layer. The first source electrode S1 and the first drain electrode D1 may extend in opposite directions to each other from the first active A1. In an embodiment, the first source electrode S1, the first active A1, and the first drain electrode D1 of the first transistor T1 may define a first semiconductor pattern. That is, the first semiconductor pattern layer may include the first semiconductor pattern.

The connection signal line CSL may be formed from the first semiconductor pattern layer and may be disposed on the buffer layer BFL. The connection signal line CSL may be electrically connected to the first semiconductor pattern of the first transistor T1 when viewed in a plane.

Although FIG. 6 shows only a portion of the first semiconductor pattern layer, it is to be understood that the first semiconductor pattern layer may be further disposed in other areas of the pixel PX (refer to FIG. 5) and the sensor FX (refer to FIG. 5).

The circuit layer DP_CL may include a plurality of insulating layers disposed on the base layer BL. FIG. 6 shows first, second, third, fourth, fifth, sixth, seventh, and eighth insulating layers 10, 20, 30, 40, 50, 60, 70, and 80 as a representative example of the insulating layers. However, the number of the insulating layers included in the circuit layer DP_CL is not limited thereto and may be changed according to the configuration of the circuit layer DP-CL or the stack process.

Each of the first to eighth insulating layers 10 to 80 may be an inorganic layer and/or an organic layer and may have a single-layer or multi-layer structure.

The inorganic layer may include at least one of, for example, aluminum oxide, titanium oxide, silicon oxide, silicon nitride, silicon oxynitride, zirconium oxide, and hafnium oxide. However, a material of the inorganic layer is not limited thereto.

The organic layer may include at least one of, for example, an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. However, a material of the organic layer is not limited thereto.

The first insulating layer 10 may be disposed on the buffer layer BFL. The first insulating layer 10 may commonly overlap the pixels PX (refer to FIG. 3) and may cover the first semiconductor pattern layer. That is, the first insulating layer 10 may cover the first semiconductor pattern of the first transistor T1 and the connection signal line CSL.

A first gate electrode G1 of the first transistor T1 may be disposed on the first insulating layer 10. The first gate electrode G1 may overlap the first active A1 of the first transistor T1 when viewed in the plane. The first gate electrode G1 may be used as a mask in a process of doping the first semiconductor pattern.

The second insulating layer 20 may be disposed on the first insulating layer 10 and may cover the first gate electrode G1. An upper electrode UE may be disposed on the second insulating layer 20. The upper electrode UE may be a portion of a metal pattern or a portion of the doped semiconductor pattern. A portion of the first gate electrode G1 and the upper electrode UE overlapping the portion of the first gate electrode G1 may define the capacitor Cst (refer to FIG. 5) of the pixel PX (refer to FIG. 5). According to an embodiment, the upper electrode UE may be omitted.

According to an embodiment, the second insulating layer 20 may be replaced with an insulating pattern. The upper electrode UE and the first gate electrode G1 may be spaced apart from each other with the insulating pattern interposed therebetween. In this case, the upper electrode UE may serve as a mask in the process of forming the insulating pattern from the second insulating layer 20.

The third insulating layer 30 may be disposed on the second insulating layer 20 and may cover the upper electrode UE. The second semiconductor pattern layer may be disposed on the third insulating layer 30. The second semiconductor pattern layer may be disposed on a layer different from a layer on which the first semiconductor pattern layer is disposed.

The second semiconductor pattern layer may include an oxide semiconductor including metal oxide. The oxide semiconductor may include a crystalline or amorphous oxide semiconductor. As an example, the oxide semiconductor may include the metal oxide of metals, such as zinc (Zn), indium (In), gallium (Ga), tin (Sn), titanium (Ti), etc., or a mixture of the metals, such as zinc (Zn), indium (In), gallium (Ga), tin (Sn), titanium (Ti), etc., and oxides thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), or the like.

The second semiconductor pattern layer may include a plurality of areas having different electrical properties depending on whether the metal oxide is reduced. An area where the metal oxide is reduced (hereinafter, referred to as a reduced area) may have a conductivity higher than that of an area where the metal oxide is not reduced (hereinafter, referred to as a non-reduced area). The reduced area may substantially act as the source electrode or the drain electrode of the transistor. The non-reduced area may substantially correspond to the active (or the channel) of the transistor.

Referring to FIG. 6, a third source electrode S3, a third active A3, and a third drain electrode D3 of the third transistor T3 may be formed from the second semiconductor pattern layer. The third source electrode S3 and the third drain electrode D3 may extend in opposite directions to each other from the third active A3. The third source electrode S3, the third active A3, and the third drain electrode D3 of the third transistor T3 may be defined as a third semiconductor pattern. That is, the second semiconductor pattern layer may include the third semiconductor pattern.

The circuit layer DP_CL may include a semiconductor pattern of the sensor driving circuit O_SD (refer to FIG. 5). FIG. 6 shows a cross-section corresponding to the reset transistor ST1 of the semiconductor pattern of the sensor driving circuit O_SD (refer to FIG. 5) as a representative example. A source electrode SS1, an active SA1, and a drain electrode SD1 of the reset transistor ST1 may be formed from the second semiconductor pattern layer. The source electrode SS1, the active SA1, and the drain electrode SD1 of the reset transistor ST1 may be defined as a semiconductor pattern of the reset transistor ST1. Accordingly, the second semiconductor pattern layer may include the third semiconductor pattern and the semiconductor pattern of the reset transistor ST1.

The fourth insulating layer 40 may be disposed on the third insulating layer 30. The fourth insulating layer 40 may cover the second semiconductor pattern layer. That is, the fourth insulating layer 40 may cover the third semiconductor pattern of the third transistor T3 and the semiconductor pattern of the reset transistor ST1.

A third gate electrode G3 of the third transistor T3 and a gate electrode SG1 of the reset transistor ST1 may be disposed on the fourth insulating layer 40. The third gate electrode G3 may overlap the third active A3 when viewed in the plane, and the gate electrode SG1 of the reset transistor ST1 may overlap the active SA1 of the reset transistor ST1 when viewed in the plane. According to an embodiment, the third gate electrode G3 or the gate electrode SG1 of the reset transistor ST1 may be provided as a single electrode or may be provided as two electrodes.

The fifth insulating layer 50 may be disposed on the fourth insulating layer 40 and may cover the third gate electrode G3 and the gate electrode SG1 of the reset transistor ST1. The sixth insulating layer 60, the seventh insulating layer 70, and the eighth insulating layer 80 may be sequentially disposed on the fifth insulating layer 50. At least one of the sixth insulating layer 60, the seventh insulating layer 70, and the eighth insulating layer 80 may include an organic layer and may provide a flat surface to components disposed thereabove.

A first connection electrode CNE1 may be disposed on the fifth insulating layer 50. The first connection electrode CNE1 may be connected to the connection signal line CSL via a contact hole CH1 defined through the first to fifth insulating layers 10 to 50. A second connection electrode CNE2 may be disposed on the sixth insulating layer 60. The second connection electrode CNE2 may be connected to the first connection electrode CNE1 via a contact hole CH2 defined through the sixth insulating layer 60. A third connection electrode CNE3 may be disposed on the seventh insulating layer 70. The third connection electrode CNE3 may be connected to the second connection electrode CNE2 via a contact hole CH5 defined through the seventh insulating layer 70.

A fourth connection electrode CNE1-1 may be disposed on the fifth insulating layer 50. The fourth connection electrode CNE1-1 may be connected to the drain electrode SD1 of the reset transistor ST1 via a contact hole CH3 defined through the fourth and fifth insulating layers 40 and 50. A fifth connection electrode CNE2-1 may be disposed on the sixth insulating layer 60. The fifth connection electrode CNE2-1 may be connected to the fourth connection electrode CNE1-1 via a contact hole CH4 defined through the sixth insulating layer 60. A sixth connection electrode CNE3-1 may be disposed on the seventh insulating layer 70. The sixth connection electrode CNE3-1 may be connected to the fifth connection electrode CNE2-1 via a contact hole CH6 defined through the seventh insulating layer 70.

According to an embodiment, at least one of the fifth to seventh insulating layers 50 to 70 may be omitted, and thus, at least one of the first to third connection electrodes CNE1 to CNE3 and the fourth to sixth connection electrodes CNE1-1 to CNE3-1 may be omitted.

The read-out line RLd may be disposed on the sixth insulating layer 60. The read-out line RLd and the second and fifth connection electrodes CNE2 and CNE2-1 may be disposed on the same layer. The read-out line RLd may be covered by the seventh insulating layer 70. According to an embodiment, the read-out line RLd and the data line DLi (refer to FIG. 5) may be disposed on the same layer, however, the layer on which the read-out line RLd is disposed is not limited thereto.

The eighth insulating layer 80 may be disposed on the seventh insulating layer 70 and may cover the third and sixth connection electrodes CNE3 and CNE3-1. The eighth insulating layer 80 may provide a base surface on which the element layer DP_ED is disposed.

The element layer DP_ED may be disposed on the circuit layer DP_CL. The element layer DP_ED may include a first light emitting element ED_R, a light receiving element OPD, and a pixel definition layer PDL. FIG. 6 shows the first light emitting element ED_R disposed in the first pixel area PXR and the light receiving element OPD disposed adjacent to the first light emitting element ED_R as a representative example, and descriptions thereof may be applied to other light emitting elements and light receiving elements included in the display panel DP.

The first light emitting element ED_R may include a first electrode R_AE, a light emitting layer R_EL, and a second electrode R_CE. The first light emitting element ED_R may include, for example, an organic light emitting element, a quantum dot light emitting element, a micro-LED light emitting element, or a nano-LED light emitting element, however, the present disclosure is not limited thereto. According to an embodiment, the first light emitting element ED_R may include various configurations as long as the first light emitting element ED_R emits the light or an amount of light emitted from the first light emitting element ED_R is controlled in response to the electrical signal.

The light receiving element OPD may include a sensing anode electrode O_AE, a photoelectric conversion layer O_RL, and a sensing cathode electrode O_CE. The light receiving element OPD may be disposed adjacent to the first light emitting element ED_R in the display area DA (refer to FIG. 3). The light receiving element OPD may be the optical sensor that senses the light incident to the light receiving element OPD and converts the light signal into the electrical signal. As an example, the light receiving element OPD may be the photodiode.

The first electrode R_AE and the sensing anode electrode O_AE may be disposed on the eighth insulating layer 80. The first electrode R_AE and the sensing anode electrode O_AE may be spaced apart from each other when viewed in the plane.

The first electrode R_AE may be connected to the third connection electrode CNE3 via a contact hole CH7 defined through the eighth insulating layer 80. The first electrode R_AE may be electrically connected to the connection signal line CSL through the first to third connection electrodes CNE1 to CNE3.

The sensing anode electrode O_AE may be connected to the sixth connection electrode CNE3-1 via a contact hole CH8 defined through the eighth insulating layer 80. The sensing anode electrode O_AE may be electrically connected to the drain electrode SD1 of the reset transistor ST1 via the fourth to sixth connection electrodes CNE1-1 to CNE3-1.

The pixel definition layer PDL may be disposed on the eighth insulating layer 80. The pixel definition layer PDL may be provided with a light emitting opening OP1 defined therethrough to expose at least a portion of the first electrode R_AE of the first light emitting element ED_R. The portion of the first electrode R_AE, which is exposed through the light emitting opening OP1, may correspond to the first pixel area PXR. The pixel definition layer PDL may be provided with a light receiving opening OP2 defined therethrough to expose at least a portion of the sensing anode electrode O_AE. The portion of the sensing anode electrode O_AE, which is exposed through the light receiving opening OP2, may correspond to the light receiving area FXA. The peripheral area NPXA may surround the first pixel area PXR and the light receiving area FXA.

The pixel definition layer PDL may include a polymer resin. As an example, the pixel definition layer PDL may include a polyacrylate-based resin or a polyimide-based resin. The pixel definition layer PDL may further include an inorganic material in addition to the polymer resin. In addition, the pixel definition layer PDL may include an inorganic material. As an example, the pixel definition layer PDL may include silicon nitride (SiNₓ), silicon oxide (SiOₓ), or silicon oxynitride (SiOₛN_{y}).

The pixel definition layer PDL may further include a light absorbing material. The pixel definition layer PDL may include a black coloring agent. The black coloring agent may include, for example, a black pigment or a black dye. The black coloring agent may include a metal material such as, for example, carbon black, chrome, etc., or an oxide thereof. However, the pixel definition layer PDL is not limited thereto.

The light emitting layer R_EL may be disposed between the first electrode R_AE and the second electrode R_CE. The light emitting layer R_EL may be disposed in an area corresponding to the light emitting opening OP1. The light emitting layer R_EL may include an organic light emitting material and/or an inorganic light emitting material. As an example, the light emitting layer R_EL may include a fluorescent or phosphorescent material, an organometallic complex light emitting material, or a quantum dot. The light emitting layer R_EL may emit a color light having one of red, green, and blue colors.

The first driving voltage ELVDD (refer to FIG. 5) and the second driving voltage ELVSS (refer to FIG. 5) may be respectively applied to the first electrode R_AE and the second electrode R_CE, and holes and electrons, which are injected into the light emitting layer R_EL, may be recombined with each other to generate excitons. The first light emitting element ED_R may emit the light when the excitons return to a ground state from an excited state, and the display panel DP may display the image through the display area DA (refer to FIG. 3).

The photoelectric conversion layer O_RL may be disposed between the sensing anode electrode O_AE and the sensing cathode electrode O_CE. The photoelectric conversion layer O_RL may be disposed in an area corresponding to the light receiving opening OP2. The photoelectric conversion layer O_RL may include a light receiving material that receives a light and converts the light to an electrical signal. The photoelectric conversion layer O_RL may include an organic light receiving material. As an example, the photoelectric conversion layer O_RL may include a conjugated polymer. The photoelectric conversion layer O_RL may include, for example, a thiophene-based conjugated polymer, a benzodithiophene-based conjugated polymer, a thieno[3,4-c]pyrrole-4,6-dione(TPD)-based conjugated polymer, a diketo-pyrrole-pyrrole(DPP)-based conjugated polymer, a benzothia diazole(BT)-based conjugated polymer, etc., however, is not limited thereto.

The second electrode R_CE of the first light emitting element ED_R and the sensing cathode electrode O_CE of the light receiving element OPD may be provided integrally with each other to form the common electrode C_CE. That is, the second electrode R_CE may correspond to a portion of the common electrode C_CE overlapping the first electrode R_AE, and the sensing cathode electrode O_CE may correspond to a portion of the common electrode C_CE overlapping the sensing anode electrode O_AE. The common electrode C_CE may be provided as a common layer and may overlap the first pixel area PXR, the light receiving area FXA, and the peripheral area NPXA.

Each of the first electrode R_AE, the sensing anode electrode O_AE, and the common electrode C_CE may include at least one selected from, two or more compounds selected from, two or more mixtures selected from, or an oxide of Ag, Mg, Cu, Al, Pt, Pd, Au, Ni, Nd, Ir, Cr, Li, Ca, LiF, Mo, Ti, W, In, Sn, and Zn.

Each of the first electrode R_AE, the sensing anode electrode O_AE, and the common electrode C_CE may be, for example, a transmissive electrode, a transflective electrode, or a reflective electrode. The transmissive electrode may include a transparent metal oxide, e.g., indium tin oxide (ITO), indium zinc oxide (IZO), zinc oxide (ZnO), indium tin zinc oxide (ITZO), etc. The transflective electrode or the reflective electrode may include, e.g., Ag, Mg, Cu, Al, Pt, Pd, Au, Ni, Nd, Ir, Cr, Li, Ca, Mo, Ti, Yb, W, a compound thereof, or a mixture thereof, e.g., AgMg, AgYb, or MgYb. The transflective electrode or the reflective electrode may have a multi-layer structure in which layers containing the above-described materials are stacked, e.g., LiF/Ca (a stack structure of LiF and Ca), LiF/Al (a stack structure of LiF and Al), or the like.

The first electrode R_AE, the sensing anode electrode O_AE, and the common electrode C_CE may have a multi-layer structure of a reflective layer formed of the above-mentioned material, a transflective layer formed of the above-mentioned material, or a transparent conductive layer formed of, for example, indium tin oxide (ITO), indium zinc oxide (IZO), zinc oxide (ZnO), or indium tin zinc oxide (ITZO). As an example, the electrode having the multi-layer structure may have a three-layer structure of ITO/Ag/ITO, however, the electrode is not limited thereto.

The encapsulation layer TFE may be disposed on the element layer DP_ED and may encapsulate the first light emitting element ED_R and the light receiving element OPD. The encapsulation layer TFE may include a plurality of thin layers. Utilizing the thin layers of the encapsulation layer TFE may increase an optical efficiency of the light emitting elements of the display element layer DP_ED and/or may protect the light emitting elements.

According to an embodiment, the encapsulation layer TFE may include inorganic layers and at least one organic layer disposed between the inorganic layers. The inorganic layer may protect elements from moisture and oxygen. As an example, the inorganic layer may include at least one of aluminum oxide, titanium oxide, silicon oxide, silicon nitride, silicon oxynitride, zirconium oxide, and hafnium oxide. The organic layer may protect elements from a foreign substance, such as dust particles. The organic layer may include an acrylic-based resin.

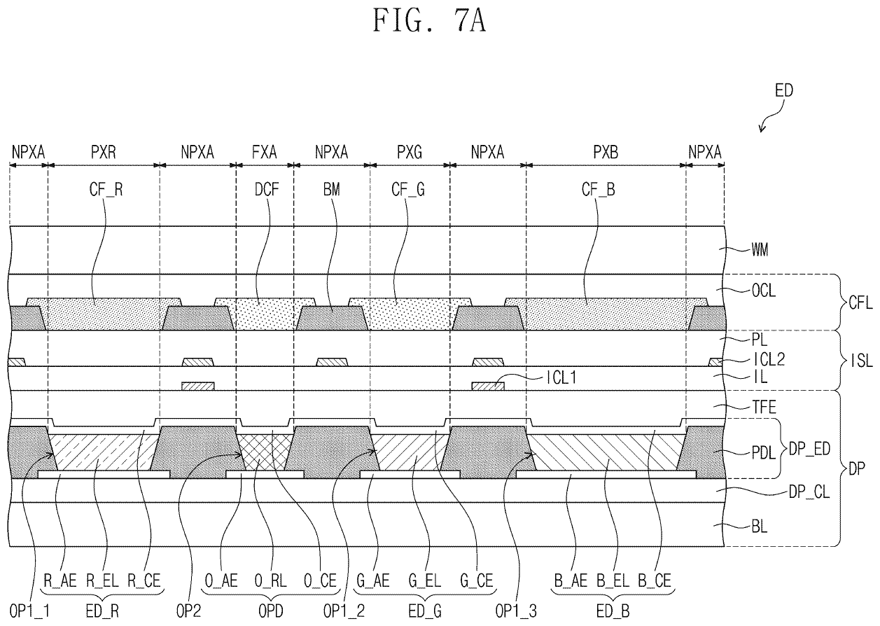

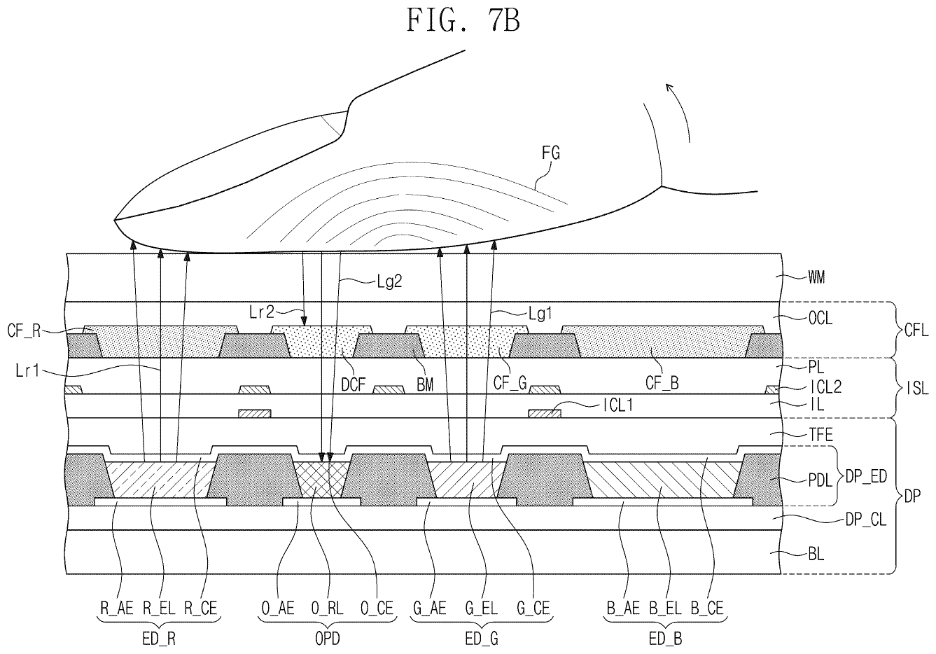

FIGS. 7A and 7B are cross-sectional views of the electronic device ED according to an embodiment of the present disclosure. For convenience of explanation, a further description of components and technical aspects previously described may be omitted.

Referring to FIGS. 7A and 7B, the element layer DP_ED may include first, second, and third light emitting elements ED_R, ED_G, and ED_B and the light receiving element OPD, which are disposed on the circuit layer DP_CL. The first, second, and third light emitting elements ED_R, ED_G, and ED_B may include first electrodes R_AE, G_AE, and B_AE, respectively, may include light emitting layers R_EL, G_EL, and B_EL, respectively, and may include second electrodes R_CE, G_CE, and B_CE, respectively. The light receiving element OPD may include the sensing anode electrode O_AE, the photoelectric conversion layer O_RL, and the sensing cathode electrode O_CE.

First, second, and third light emitting openings OP1_1, OP1_2, and OP1_3 and the light receiving opening OP2 may be defined through the pixel definition layer PDL. The first, second, and third light emitting elements ED_R, ED_G, and ED_B may be disposed to correspond to the first, second, and third light emitting openings OP1_1, OP1_2, and OP1_3, respectively. The light receiving element OPD may be disposed to correspond to the light receiving opening OP2.

The first electrodes R_AE, G_AE, and B_AE and the sensing anode electrode O_AE may be disposed on the same layer and may be spaced apart from each other. The first electrodes R_AE, G_AE, and B_AE and the sensing anode electrode O_AE may be substantially simultaneously formed through the same process. At least a portion of each of the first electrodes R_AE, G_AE, and B_AE may be exposed through a corresponding opening among the first, second, and third light emitting openings OP1_1, OP1_2, and OP1_3. At least a portion of the sensing anode electrode O_AE may be exposed through the light receiving opening OP2.

Areas in which the first, second, and third light emitting elements ED_R, ED_G, and ED_B are disposed may correspond to the first, second, and third pixel areas PXR, PXG, and PXB, respectively. The lights exiting through the first, second, and third pixel areas PXR, PXG, and PXB may have different colors from each other. The peripheral area NPXA may surround the first, second, and third pixel areas PXR, PXG, and PXB, may define a boundary between the first, second, and third pixel areas PXR, PXG, and PXB, and may prevent colors from being mixed with each other between the first, second, and third pixel areas PXR, PXG, and PXB.

An area in which the light receiving element OPD is disposed may correspond to the light receiving area FXA. The peripheral area NPXA may surround the light receiving area FXA. The light receiving area FXA surrounded by the peripheral area NPXA may be distinguished from the first, second, and third pixel areas PXR, PXG, and PXB.

The light emitting layers R_EL, G_EL, and B_EL of the first, second, and third light emitting elements ED_R, ED_G, and ED_B may be respectively disposed in the first, second, and third light emitting openings OP1_1, OP1_2, and OP1_3. That is, the light emitting layers R_EL, G_EL, and B_EL of the first, second, and third light emitting elements ED_R, ED_G, and ED_B may be formed in a pattern shape to be separated from each other. Each of the light emitting layers R_EL, G_EL, and B_EL may include an organic material and/or an inorganic material and may generate a predetermined color light. In addition, the light emitting layers R_EL, G_EL, and B_EL may have a multi-layer structure that is called a tandem.

The light emitting layers R_EL, G_EL, and B_EL of the first, second, and third light emitting elements ED_R, ED_G, and ED_B may generate different color lights from each other, however, are not limited thereto. According to an embodiment, the light emitting layers R_EL, G_EL, and B_EL of the first, second, and third light emitting elements ED_R, ED_G, and ED_B may be commonly disposed in the first, second, and third pixel areas PXR, PXG, and PXB and may emit a source light having the same color, e.g., a blue light or a white light.

The photoelectric conversion layer O_RL may be disposed in the light receiving opening OP2. For convenience of explanation, a duplicative description of the photoelectric conversion layer O_RL, which is described above, is omitted.

The second electrodes R_CE, G_CE, and B_CE of the first, second, and third light emitting elements ED_R, ED_G, and ED_B may be electrically connected to each other. As an example, the second electrodes R_CE, G_CE, and B_CE of the first, second, and third light emitting elements ED_R, ED_G, and ED_B may be provided integrally with each other. The second electrodes R_CE, G_CE, and B_CE may be provided integrally with the sensing cathode electrode O_CE of the light receiving element OPD. Accordingly, the second electrodes R_CE, G_CE, and B_CE and the sensing cathode electrode O_CE may be connected integrally to each other and may be defined as the common electrode C_CE (refer to FIG. 6) overlapping the first, second, and third pixel areas PXR, PXG, and PXB, the peripheral area NPXA, and the light receiving area FXA.

The electronic device ED may include an input sensing layer ISL disposed on the display panel DP and a color filter layer CFL disposed on the input sensing layer ISL.

The input sensing layer ISL may be disposed directly on the encapsulation layer TFE. The input sensing layer ISL may be coupled to the encapsulation layer TFE by a separate adhesive. The input sensing layer ISL may include a first conductive layer ICL1, an intermediate insulating layer IL, a second conductive layer ICL2, and a protective layer PL.

The first conductive layer ICL1 may be disposed on the encapsulation layer TFE. FIGS. 7A and 7B show a structure in which the first conductive layer ICL1 is disposed directly on the encapsulation layer TFE, however, the present disclosure is not limited thereto. As an example, the input sensing layer ISL may further include a base insulating layer disposed between the first conductive layer ICL1 and the encapsulation layer TFE and including an inorganic insulating material. In this case, the encapsulation layer TFE may be covered by the base insulating layer, and the first conductive layer ICL1 may be disposed on the base insulating layer.

The intermediate insulating layer IL may cover the first conductive layer ICL1. The second conductive layer ICL2 may be disposed on the intermediate insulating layer IL. FIGS. 7A and 7B show a structure in which the input sensing layer ISL includes the first and second conductive layers ICL1 and ICL2, however, the present disclosure is not limited thereto. As an example, the input sensing layer ISL may include only one of the first and second conductive layers ICL1 and ICL2.

The protective layer PL may cover the second conductive layer ICL2. The protective layer PL may include an organic insulating material. The protective layer PL may protect the first and second conductive layers ICL1 and ICL2 from moisture and oxygen.

The color filter layer CFL may be disposed on the input sensing layer ISL. The color filter layer CFL may be disposed directly on the protective layer PL. The color filter layer CFL may include a first color filter CF_R, a second color filter CF_G, and a third color filter CF_B.

The first color filter CF_R may have a first color, the second color filter CF_G may have a second color, and the third color filter CF_B may have a third color. The first to third colors may be different from each other. As an example, the first color may be a red color, the second color may be a green color, and the third color may be a blue color, however, the present disclosure is not limited thereto.

As the color filter layer CFL includes the first, second, and third color filters CF_R, CF_G, and CF_B respectively corresponding to the first, second, and third pixel areas PXR, PXG, and PXB, the color filter layer CFL may filter the light incident thereto from the outside of the electronic device ED and may reduce a reflectance of the electronic device ED with respect to the external light.

The color filter layer CFL may further include a dummy color filter DCF. The dummy color filter DCF may be disposed to correspond to the light receiving area FXA. The dummy color filter DCF may overlap the light receiving element OPD. The dummy color filter DCF may have the same color as one of the first, second, and third color filters CF_R, CF_G, and CF_B. As an example, the dummy color filter DCF may have the same color, e.g., the green color, as that of the second color filter CF_G, however, the dummy color filter DCF is not limited thereto. According to an embodiment, the dummy color filter DCF may be omitted. In this case, according to an embodiment, the color filter is not disposed on the light receiving element OPD.

The color filter layer CFL may further include a black matrix BM. The black matrix BM may be disposed to correspond to the peripheral area NPXA. The black matrix BM may overlap the first and second conductive layers ICL1 and ICL2 of the input sensing layer ISL. The black matrix BM may absorb the external light incident thereto from the outside of the electronic device ED, which may prevent the external light from being reflected by the first and second conductive layers ICL1 and ICL2.

The color filter layer CFL may further include an overcoating layer OCL. The overcoating layer OCL may include an organic insulating material. The overcoating layer OCL may have a predetermined thickness large enough to compensate for a step difference between the first, second, and third color filters CF_R, CF_G, and CF_B. A material for the overcoating layer OCL is not particularly limited, as long as the overcoating layer OCL includes a material appropriate for planarizing an upper surface of the color filter layer CFL. As an example, the overcoating layer OCL may include an acrylate-based organic material.

The window WM may be disposed on the color filter layer CFL. The window WM may be disposed on the overcoating layer OCL that provides the flat upper surface, however, the present disclosure is not limited thereto. According to an embodiment, a separate adhesive layer may be further disposed between the window WM and the overcoating layer OCL, and the window WM may be coupled to the color filter layer CFL by an adhesive layer.

Referring to FIG. 7B, when the electronic device ED operates, each of the first, second, and third light emitting elements ED_R, ED_G, and ED_B may emit the light. As an example, the first light emitting element ED_R may emit the red light, the second light emitting element ED_G may emit the green light, and the third light emitting element ED_B may emit the blue light.

As an example, the light receiving element OPD may receive the light from specific light emitting elements, e.g., the second light emitting element ED_G emitting the green light, among the first, second, and third light emitting elements ED_R, ED_G, and ED_B. That is, the light receiving element OPD may receive a second reflected light Lg2 corresponding to a second light Lg1 emitted from the second light emitting element ED_G and reflected by the user's fingerprint FG. The second light Lg1 and the second reflected light Lg2 may be the green light in a green wavelength band. The dummy color filter DCF having the green color may be disposed above the light receiving element OPD. Accordingly, the second reflected light Lg2 in the green wavelength band may be incident to the light receiving element OPD after passing through the dummy color filter DCF.

The red light and the blue light emitted from the first and third light emitting elements ED_R and ED_B may also be reflected by the user's hand. As an example, in an embodiment, when a red light Lr1 emitted from the first light emitting element ED_R and reflected by the user's hand is defined as a first reflected light Lr2, the first reflected light Lr2 does not pass through the dummy color filter DCF having the green light and may be absorbed by the dummy color filter DCF. Accordingly, the first reflected light Lr2 that does not pass through the dummy color filter DCF is not incident to the light receiving element OPD in an embodiment. Similarly, even though the blue light is reflected by the user's hand, the reflected blue light may be absorbed by the dummy color filter DCF having the green light. Accordingly, only the second reflected light Lg2 may be provided to the light receiving element OPD.

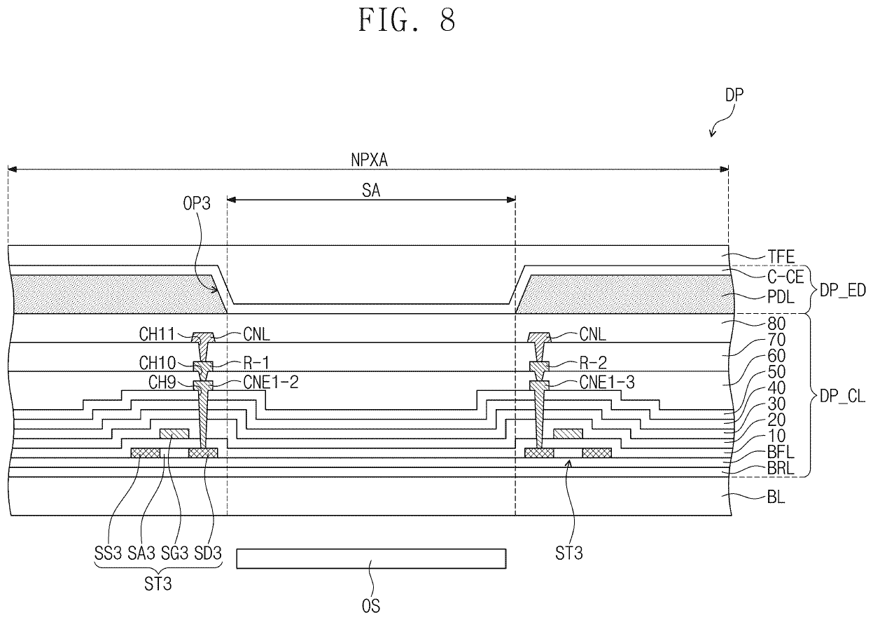

FIG. 8 is a cross-sectional view of the display panel DP and the optical sensor OS according to an embodiment of the present disclosure.

Referring to FIG. 8, the optical sensor OS may be disposed under the display panel DP. The optical sensor OS may overlap the transmission area SA.

FIG. 8 shows a cross-section of the output transistors ST3 included in the circuit layer DP_CL. Each of the output transistors ST3 may include a source electrode SS3, an active SA3, a drain electrode SD3, and a gate electrode SG3. The output transistors ST3 may have substantially the same structure as that of the first transistor T1 (refer to FIG. 6).

The output transistors ST3 may be spaced apart from the transmission area SA. That is, the output transistors ST3 may be disposed such that it does not overlap the transmission area SA. Thus, deterioration of the reliability and sensitivity of the optical sensor OS that receives or emits the light through the transmission area SA may be prevented.

Seventh and eighth connection electrodes CNE1-2 and CNE1-3 may be connected to the output transistors ST3, respectively. The seventh connection electrode CNE1-2 may be disposed on the fifth insulating layer 50 and may be connected to the drain electrode SD3 of the output transistor ST3 via a contact hole CH9 defined through the first to fifth insulating layers 10 to 50. The eighth connection electrode CNE1-3 may be spaced apart from the seventh connection electrode CNE1-2 and may be connected to the drain electrode SD3 of another output transistor ST3. In an embodiment, the seventh and eighth connection electrodes CNE1-2 and CNE1-3 do not overlap the transmission area SA.

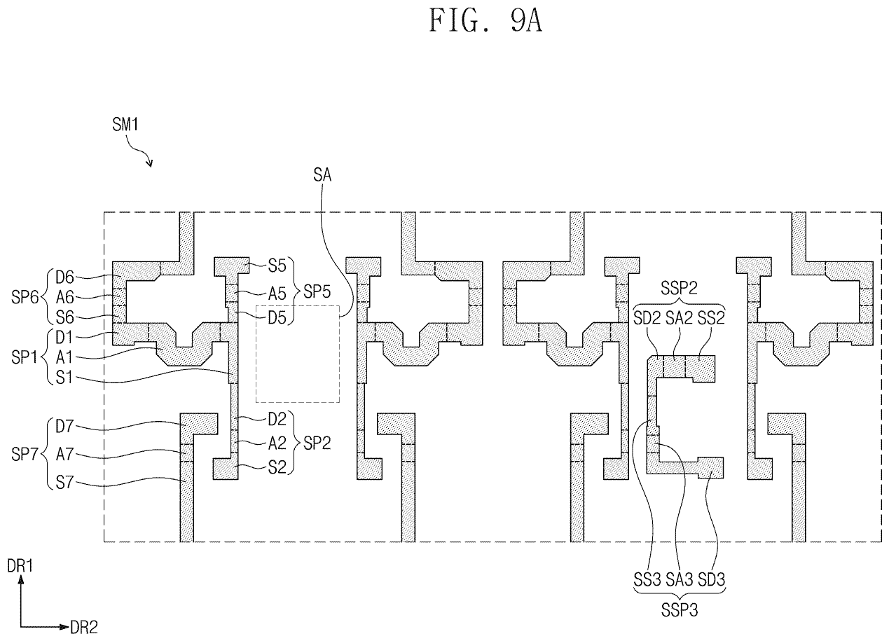

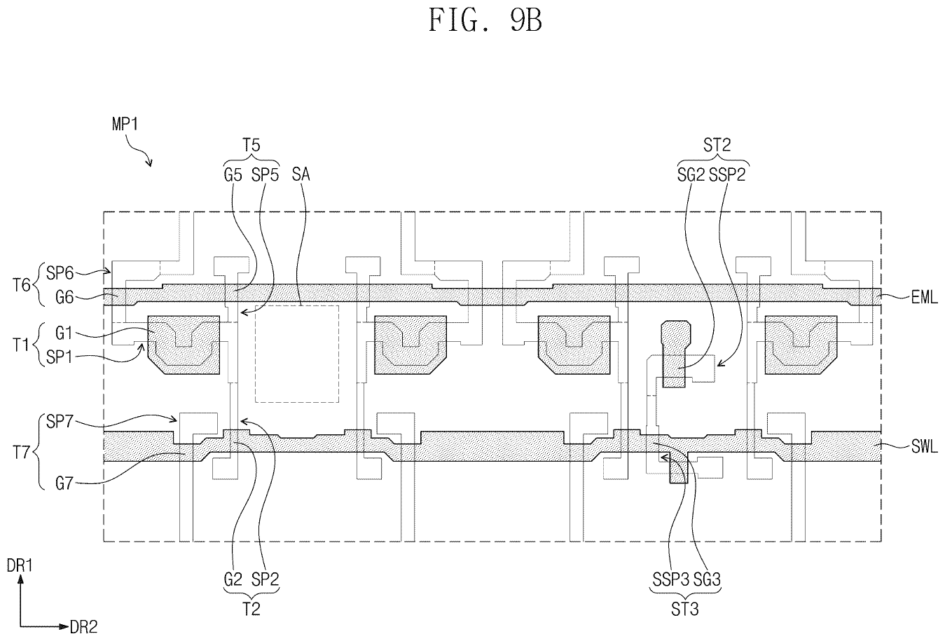

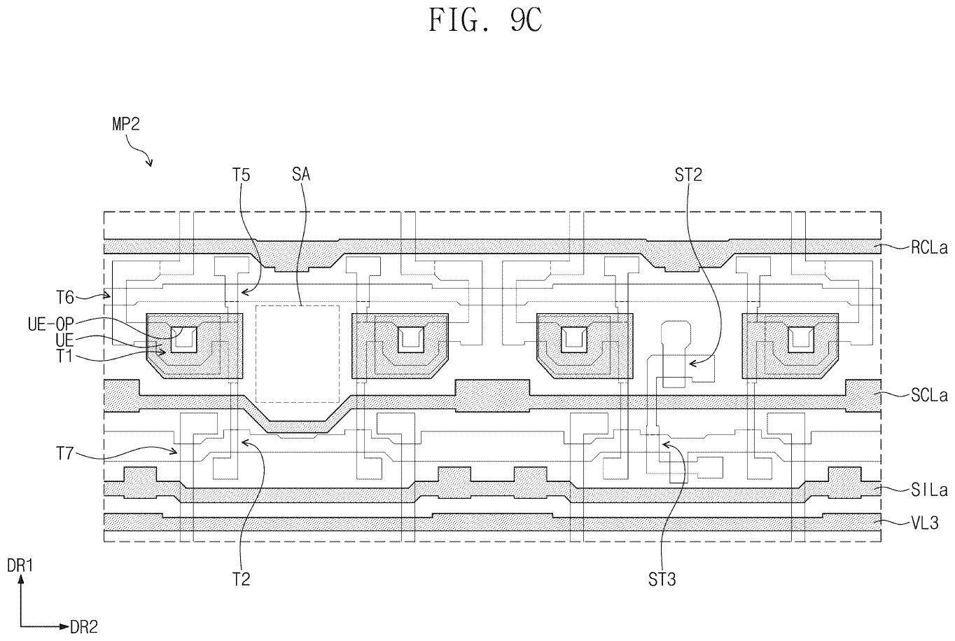

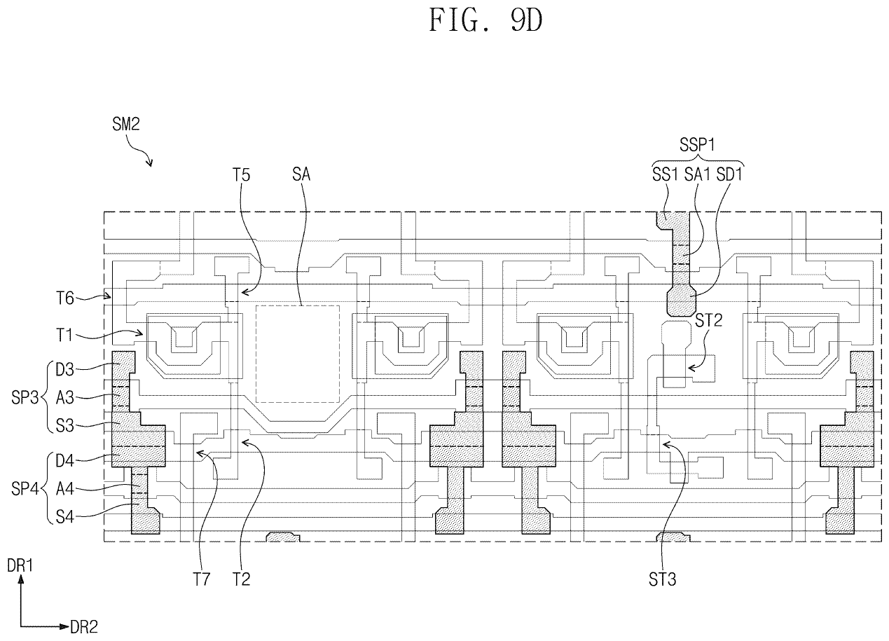

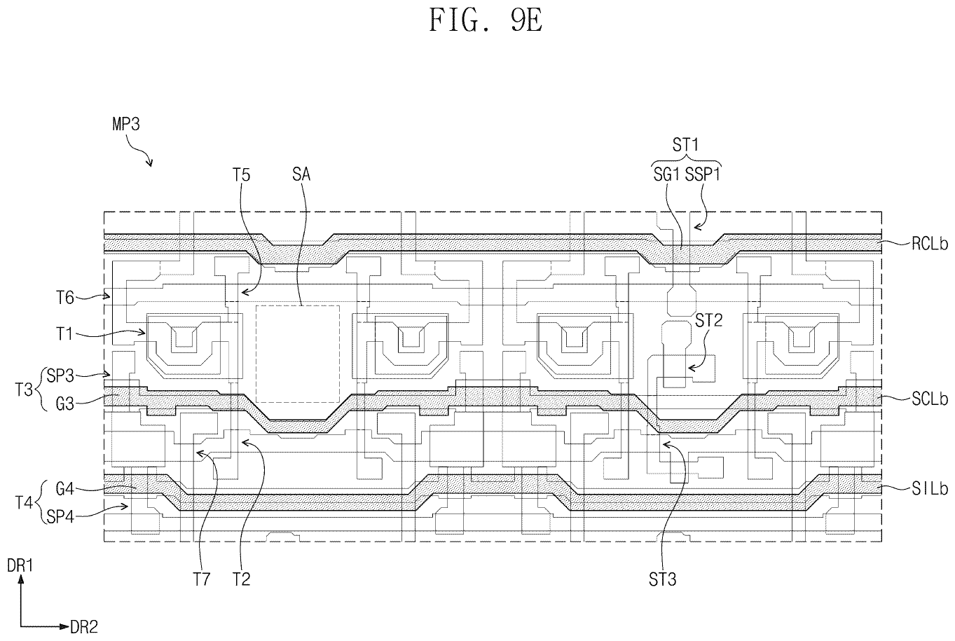

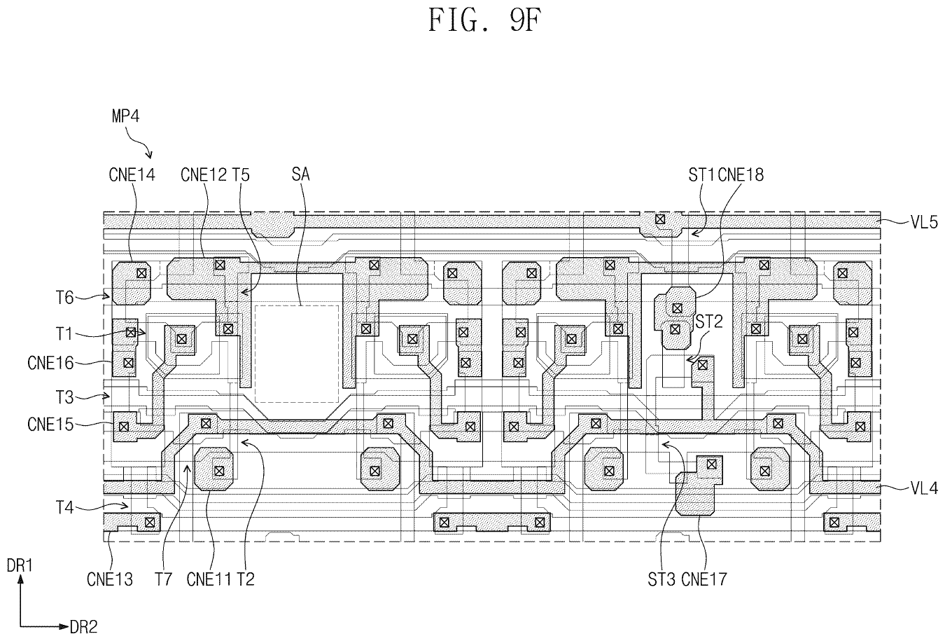

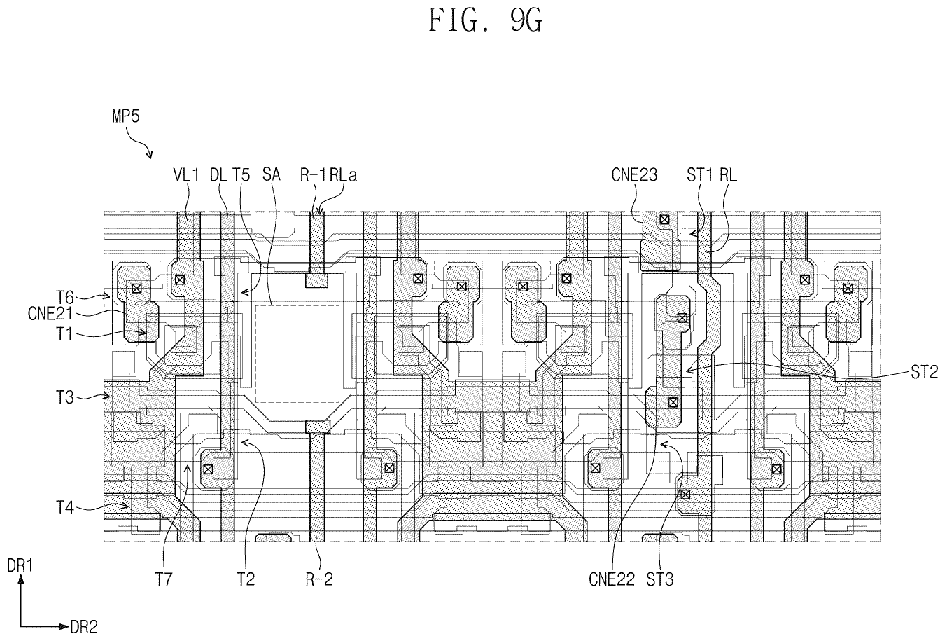

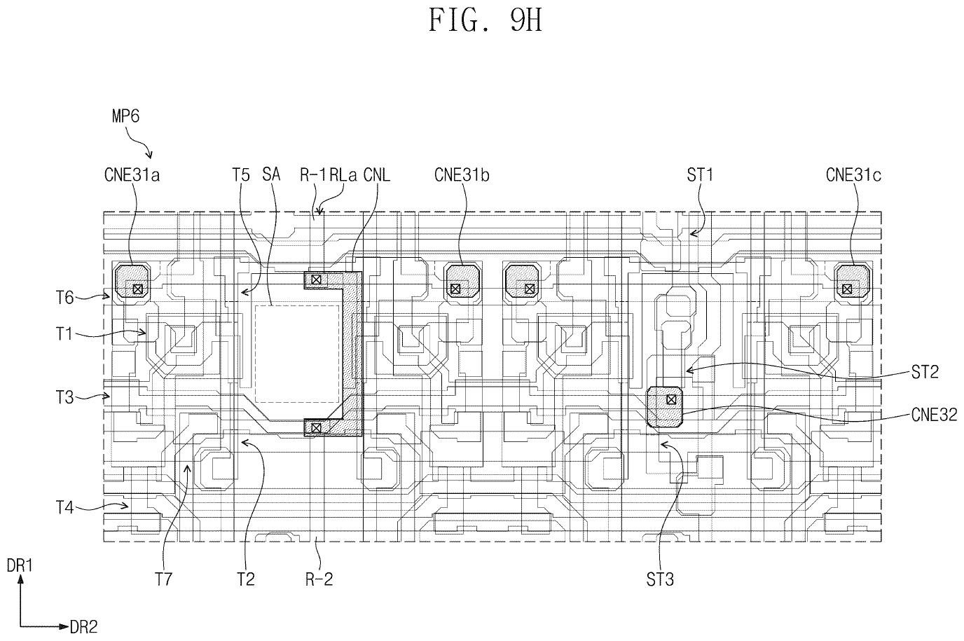

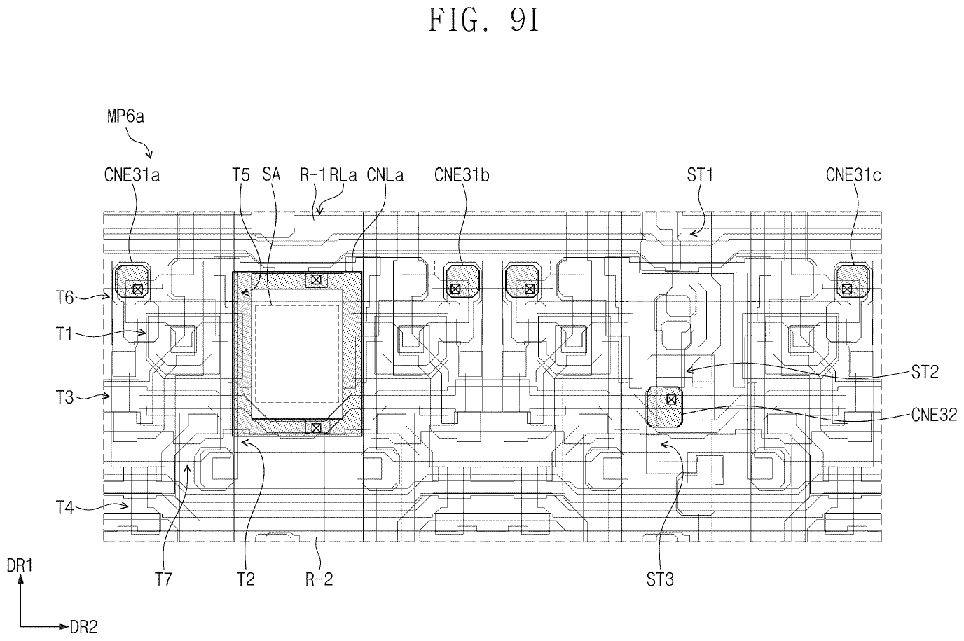

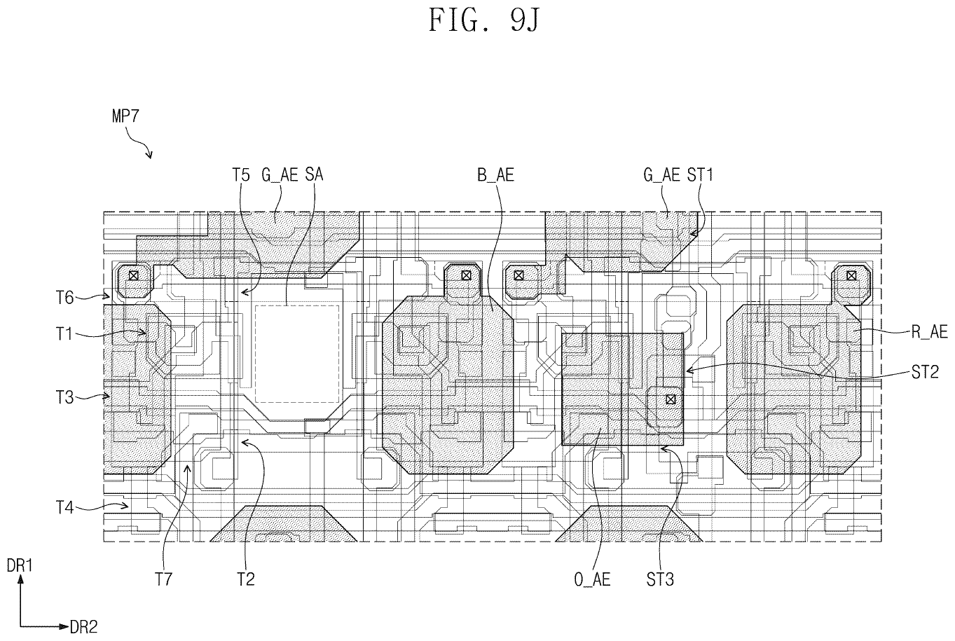

A first line R-1 and a second line R-2 which form the read-out line RLd (refer to FIG. 5) may be disposed on the sixth insulating layer 60. The first line R-1 and the second line R-2 may be spaced apart from each other with the transmission area SA interposed therebetween in one direction. That is, in an embodiment, the first line R-1 and the second line R-2 do not overlap the transmission area SA. Accordingly, the light passing through the transmission area SA may be prevented from being reflected by the first line R-1 and the second line R-2, and thus, deterioration of the reliability and the sensitivity of the optical sensor OS may be prevented, as described in further detail with reference to FIG. 9G.

A connection line CNL may be disposed on the seventh insulating layer 70 and may be connected to each of the first line R-1 and the second line R-2. The connection line CNL connecting the first line R-1 and the second line R-2 may form one read-out line RLd (refer to FIG. 5) together with the first line R-1 and the second line R-2.

The connection line CNL may be placed to detour the transmission area SA when viewed in the plane. That is, in an embodiment, the connection line CNL does not overlap the transmission area SA and may electrically connect the first line R-1 and the second line R-2. Accordingly, in an embodiment, the connection line CNL does not cause deterioration in transmittance of the transmission area SA, as described in further detail with reference to FIGS. 9H and 9I.

A transmission opening OP3 spaced apart from the light emitting opening OP1 (refer to FIG. 6) and the light receiving opening OP2 (refer to FIG. 6) may be defined through the pixel definition layer PDL. The transmission opening OP3 may overlap the transmission area SA when viewed in the plane. As the transmission opening OP3 is defined through the pixel definition layer PDL to correspond to the transmission area SA, the light transmittance of the transmission area SA may be increased.

The common electrode C_CE may be disposed on the pixel definition layer PDL. The common electrode C_CE may be provided as a transparent electrode and may overlap the transmission area SA, however, the present disclosure is not limited thereto. According to an embodiment, the common electrode C_CE is not disposed in the transmission area SA.

FIGS. 9A to 9J are plan views illustrating patterns forming a pixel and a sensor in order of arrangement according to an embodiment of the present disclosure.

The circuit layer DP_CL (refer to FIG. 6) may include a semiconductor pattern layer and a conductive pattern layer. Each of the semiconductor pattern layer and the conductive pattern layer may include patterns arranged in a predetermined rule when viewed in the plane, and the patterns may form the pixel driving circuit P_PD (refer to FIG. 5) and the sensor driving circuit O_SD (refer to FIG. 5). FIGS. 9A to 9J show plan views of portions of the pixel driving circuit P_PD (refer to FIG. 5) and the sensor driving circuit O_SD (refer to FIG. 5).

Referring to FIG. 9A, the first semiconductor pattern layer SM1 may include first, second, fifth, sixth, and seventh semiconductor patterns SP1, SP2, SP5, SP6, and SP7 forming the pixel driving circuit P_PD (refer to FIG. 5) and semiconductor patterns SSP2 and SSP3 (hereinafter, referred to as an eighth semiconductor pattern SSP2 and a ninth semiconductor pattern SSP3) forming the sensor driving circuit O_SD (refer to FIG. 5). The first semiconductor pattern layer SM1 may be disposed on the buffer layer BFL (refer to FIG. 6). The first semiconductor pattern layer SM1 may include a silicon semiconductor. As an example, the silicon semiconductor may include amorphous silicon, polycrystalline silicon, or the like.

The first, second, fifth, sixth, and seventh semiconductor patterns SP1, SP2, SP5, SP6, and SP7 may include source electrodes S1, S2, S5, S6, and S7, respectively, may include drain electrodes D1, D2, D5, D6, and D7, respectively, and may include actives A1, A2, A5, A6, and A7, respectively. The first semiconductor pattern SP1 may be connected to each of the second semiconductor pattern SP2, the fifth semiconductor pattern SP5, and the sixth semiconductor pattern SP6. The sixth semiconductor pattern SP6 may be connected to the seventh semiconductor pattern SP7.

The first, second, fifth, sixth, and seventh semiconductor patterns SP1, SP2, SP5, SP6, and SP7 forming the pixel driving circuit P_PD (refer to FIG. 5) may be repeatedly arranged in a structure that is symmetrical with those forming adjacent pixel driving circuit P_PD (refer to FIG. 5) in the second direction DR2 when viewed in the plane, however, the present disclosure is not limited thereto. According to an embodiment, the first, second, fifth, sixth, and seventh semiconductor patterns SP1, SP2, SP5, SP6, and SP7 forming the pixel driving circuit P_PD (refer to FIG. 5) may be repeatedly arranged in a structure that is the same as those forming adjacent driving circuit P_PD when viewed in the plane.

The eighth semiconductor pattern SSP2 may include a source electrode SS2, a drain electrode SD2, and an active SA2, and the ninth semiconductor pattern SSP3 may include a source electrode SS3, a drain electrode SD3, and an active SA3. The eighth semiconductor pattern SSP2 and the ninth semiconductor pattern SSP3 may be connected to each other. The eighth semiconductor pattern SSP2 and the ninth semiconductor pattern SSP3, which form the sensor driving circuit O_SD (refer to FIG. 5), may be disposed between the semiconductor patterns SP1, SP2, SP5, SP6, and SP7 forming the pixel driving circuit P_PD (refer to FIG. 5) when viewed in the plane.

The transmission area SA may be defined in a portion of areas between the patterns of the first semiconductor pattern layer SM1. The first semiconductor pattern layer SM1 may be spaced apart from the transmission area SA. That is, in an embodiment, the first semiconductor pattern layer SM1 does not overlap the transmission area SA. For example, the transmission area SA may be spaced apart from the first, second, fifth, sixth, seventh, eighth, ninth semiconductor patterns SP1, SP2, SP5, SP6, SP7, SSP2, and SSP3. Accordingly, the transmission area SA may have a high light transmittance.

Referring to FIG. 9B, a first conductive pattern layer MP1 may be disposed on the first semiconductor pattern layer SM1 (refer to FIG. 9A). The first conductive pattern layer MP1 may be disposed on the first insulating layer 10 (refer to FIG. 6). The first conductive pattern layer MP1 may include gate electrodes G1 and SG2, a light emission control line EML, and a first scan line SWL.

The first conductive pattern layer MP1 may include, for example, a metal, alloy, conductive metal oxide, or transparent conductive material. As an example, the first conductive pattern layer MP1 may include silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), indium tin oxide (ITO), indium zinc oxide (IZO), or the like, however, the first conductive pattern layer MP1 is not limited thereto. Descriptions about the material included in the first conductive pattern layer MP1 may be applied to other conductive pattern layers described below.

The gate electrode G1 of the gate electrodes G1 and SG2 may overlap the first semiconductor pattern SP1 and may correspond to the first gate electrode G1. The first semiconductor pattern SP1 and the first gate electrode G1 may form the first transistor T1.

The other gate electrode SG2 of the gate electrodes G1 and GS2 except the first gate electrode G1 may overlap the eighth semiconductor pattern SSP2 and may be defined as an eighth gate electrode SG2. The eighth semiconductor pattern SSP2 and the eighth gate electrode SG2 may form the amplification transistor ST2.

The first and eighth gate electrodes G1 and SG2 may be arranged in an island shape. That is, the first and eighth gate electrodes G1 and SG2 may be spaced apart from each other when viewed in the plane.

The light emission control line EML may extend in the second direction DR2 when viewed in the plane and may overlap each of the fifth semiconductor pattern SP5 and the sixth semiconductor pattern SP6. A portion of the light emission control line EML, which overlaps the fifth semiconductor pattern SP5, may correspond to a fifth gate electrode G5. The fifth semiconductor pattern SP5 and the fifth gate electrode G5 may form the fifth transistor T5. A portion of the light emission control line EML, which overlaps the sixth semiconductor pattern SP6, may correspond to a sixth gate electrode G6. The sixth semiconductor pattern SP6 and the sixth gate electrode G6 may form the sixth transistor T6.

The first scan line SWL may extend in the second direction DR2 when viewed in the plane and may overlap each of the second semiconductor pattern SP2 and the seventh semiconductor pattern SP7. A portion of the first scan line SWL, which overlaps the second semiconductor pattern SP2, may correspond to a second gate electrode G2, and the second semiconductor pattern SP2 and the second gate electrode G2 may form the second transistor T2. A portion of the first scan line SWL, which overlaps the seventh semiconductor pattern SP7, may correspond to a seventh gate electrode G7, and the seventh semiconductor pattern SP7 and the seventh gate electrode G7 may form the seventh transistor T7.

The first scan line SWL may overlap the ninth semiconductor pattern SSP3 when viewed in the plane. A portion of the first scan line SWL, which overlaps the ninth semiconductor pattern SSP3, may correspond to a ninth gate electrode SG3, and the ninth semiconductor pattern SSP3 and the ninth gate electrode SG3 may form the output transistor ST3.

The first scan line SWL may correspond to the write scan line SWLj of FIG. 5, and the write scan signal may be applied to the first scan line SWL.

The first conductive pattern layer MP1 may be spaced apart from the transmission area SA when viewed in the plane. That is, in an embodiment, the patterns of the first conductive pattern layer MP1 do not overlap the transmission area SA. For example, the transmission area SA may be spaced apart from the first and eighth gate electrodes G1 and SG2, the light emission control line EML, and the first scan line SWL. Accordingly, the light traveling to the transmission area SA has a high probability of passing through the transmission area SA without being reflected.

Referring to FIG. 9C, a second conductive pattern layer MP2 may be disposed on the first conductive pattern layer MP1 (refer to FIG. 9B). The second conductive pattern layer MP2 may be disposed on the second insulating layer 20 (refer to FIG. 6). The second conductive pattern layer MP2 may include an upper electrode UE, a second scan line SCLa, a third scan line SILa, a first reset control line RCLa, and a voltage line VL3.

The upper electrode UE may overlap the first gate electrode G1 (refer to FIG. 9B). The upper electrode UE may be spaced apart from signal lines included in the second conductive pattern layer MP2 and may be arranged in an island shape. The upper electrode UE and the first gate electrode G1 (refer to FIG. 9B) may form the capacitor Cst (refer to FIG. 5). That is, the portion of the first gate electrode G1 (refer to FIG. 9B) overlapping the upper electrode UE and the portion of the upper electrode UE overlapping the first gate electrode G1 (refer to FIG. 9B) may form the capacitor Cst (refer to FIG. 5). The upper electrode UE may be provided with an opening UE-OP defined therethrough. A portion of the first gate electrode G1 (refer to FIG. 9B) may be exposed through the opening UE-OP of the upper electrode UE.

The first reset control line RCLa may extend in the second direction DR2 when viewed in the plane. The first reset control line RCLa may correspond to the reset control line RCL of FIG. 5, and the reset control signal may be applied to the first reset control line RCLa.

The second scan line SCLa may extend in the second direction DR2 when viewed in the plane. The second scan line SCLa may correspond to the compensation scan line SCLj of FIG. 5, and the compensation scan signal may be applied to the second scan line SCLa.

The third scan line SILa may extend in the second direction DR2 when viewed in the plane. The third scan line SILa may correspond to the initialization scan line SILj of FIG. 5, and the initialization scan signal may be applied to the third scan line SILa.

The voltage line VL3 may extend in the second direction DR2 when viewed in the plane. The voltage line VL3 may correspond to the third voltage line VL3 of FIG. 5. The first initialization voltage VINT1 (refer to FIG. 5) may be provided via the voltage line VL3 of the second conductive pattern layer MP2.

The second conductive pattern layer MP2 may be spaced apart from the transmission area SA when viewed in the plane. That is, in an embodiment, the patterns of the second conductive pattern layer MP2 do not overlap the transmission area SA. For example, the transmission area SA may be spaced apart from the upper electrode UE, the second scan line SCLa, the third scan line SILa, the first reset control line RCLa, and the voltage line VL3. Accordingly, the light traveling to the transmission area SA has a high probability of passing through the transmission area SA without being reflected.

Referring to FIG. 9D, the second semiconductor pattern layer SM2 may include third and fourth semiconductor patterns SP3 and SP4 forming the pixel driving circuit P_PD (refer to FIG. 5) and a semiconductor pattern SSP1 (hereinafter, referred to as a tenth semiconductor pattern SSP1) forming the sensor driving circuit O_SD (refer to FIG. 5). The second semiconductor pattern layer SM2 and the first semiconductor pattern layer SM1 (refer to FIG. 9A) may be disposed on different layers from each other. As an example, the second semiconductor pattern layer SM2 may be disposed on the third insulating layer 30 (refer to FIG. 6). The second semiconductor pattern layer SM2 may include an oxide semiconductor containing metal oxide.

The third semiconductor pattern SP3 may include a source electrode S3, a drain electrode D3, and an active A3, and the fourth semiconductor pattern SP4 may include a source electrode S4, a drain electrode D4, and an active A4. The third semiconductor pattern SP3 and the fourth semiconductor pattern SP4 may be connected to each other.

The third and fourth semiconductor patterns SP3 and SP4 forming the pixel driving circuit P_PD (refer to FIG. 5) may be repeatedly arranged in a structure that is symmetrical with those forming adjacent pixel driving circuit P_PD (refer to FIG. 5) in the second direction DR2 when viewed in the plane, however, the present disclosure is not limited thereto. According to an embodiment, the third and fourth semiconductor patterns SP3 and SP4 forming the pixel driving circuit P_PD (refer to FIG. 5) may be repeatedly arranged in a structure that is the same as those forming an adjacent pixel driving circuit P_PD (refer to FIG. 5) when viewed in the plane.

The tenth semiconductor pattern SSP1 may include a source electrode SS1, a drain electrode SD1, and an active SA1. The tenth semiconductor pattern SSP1 may be spaced apart from the third and fourth semiconductor patterns SP3 and SP4 when viewed in the plane.

The second semiconductor pattern layer SM2 may be spaced apart from the transmission area SA when viewed in the plane. That is, in an embodiment, the second semiconductor pattern layer SM2 does not overlap the transmission area SA. For example, the transmission area SA may be spaced apart from the third, fourth, and tenth semiconductor patterns SP3, SP4, and SSP1. Accordingly, the transmission area SA may have a relatively high light transmittance.

Referring to FIG. 9E, a third conductive pattern layer MP3 may be disposed on the second semiconductor pattern layer SM2 (refer to FIG. 9D). The third conductive pattern layer MP3 may be disposed on the fourth insulating layer 40 (refer to FIG. 6). The third conductive pattern layer MP3 may include a second reset control line RCLb, a fourth scan line SCLb, and a fifth scan line SILb.

The fourth scan line SCLb may extend in the second direction DR2 when viewed in the plane and may overlap the third semiconductor pattern SP3. A portion of the fourth scan line SCLb, which overlaps the third semiconductor pattern SP3, may correspond to the third gate electrode G3. The third semiconductor pattern SP3 and the third gate electrode G3 may form the third transistor T3.

The fourth scan line SCLb may be electrically connected to the second scan line SCLa (refer to FIG. 9C) via a contact portion. Accordingly, the compensation scan signal applied to the second scan line SCLa (refer to FIG. 9C) may be provided to the fourth scan line SCLb. The fourth scan line SCLb may correspond to the compensation scan line SCLj of FIG. 5.

The fifth scan line SILb may extend in the second direction DR2 when viewed in the plane and may overlap the fourth semiconductor pattern SP4. A portion of the fifth scan line SILb, which overlaps the fourth semiconductor pattern SP4, may correspond to a fourth gate electrode G4. The fourth semiconductor pattern SP4 and the fourth gate electrode G4 may form the fourth transistor T4.

The fifth scan line SILb may be electrically connected to the third scan line SILa (refer to FIG. 9C) via a contact portion. Accordingly, the initialization scan signal applied to the third scan line SILa (refer to FIG. 9C) may be provided to the fifth scan line SILb. The fifth scan line SILb may correspond to the initialization scan line SILj of FIG. 5.

The second reset control line RCLb may extend in the second direction DR2 when viewed in the plane and may overlap the tenth semiconductor pattern SSP1. A portion of the second reset control line RCLb, which overlaps the tenth semiconductor pattern SSP1, may correspond to a tenth gate electrode SG1. The tenth semiconductor pattern SSP1 and the tenth gate electrode SG1 may form the reset transistor ST1.

The second reset control line RCLb may be electrically connected to the first reset control line RCLa (refer to FIG. 9C) via a contact portion. Accordingly, the reset control signal applied to the first reset control line RCLa (refer to FIG. 9C) may be transmitted to the second reset control line RCLb. The second reset control line RCLb may correspond to the reset control line RCL of FIG. 5.

In an embodiment, the third conductive pattern layer MP3 may be spaced apart from and does not overlap the transmission area SA when viewed in the plane. For example, the transmission area SA may be spaced apart from the second reset control line RCLb, the fourth scan line SCLb, and the fifth scan line SILb. Accordingly, the light traveling to the transmission area SA has a high probability of passing through the transmission area SA without being reflected.

Referring to FIG. 9F, a fourth conductive pattern layer MP4 may be disposed on the third conductive pattern layer MP3 (refer to FIG. 9E). The fourth conductive pattern layer MP4 may be disposed on the fifth insulating layer 50 (refer to FIG. 6). The fourth conductive pattern layer MP4 may include voltage lines VL4 and VL5 and a plurality of connection patterns CNE11 to CNE18.

The voltage lines VL4 and VL5 may extend in the second direction DR2 when viewed in the plane. The voltage lines VL4 and VL5 may correspond to the fourth voltage line VL4 and the fifth voltage line VL5, respectively.

The fourth voltage line VL4 may be connected to the drain electrode D7 (refer to FIG. 9A) of the seventh transistor T7 via a contact portion. The fourth voltage line VL4 may apply the second initialization voltage VINT2 (refer to FIG. 5) to the seventh transistor T7.

The fifth voltage line VL5 may be connected to the source electrode SS1 (refer to FIG. 9D) of the reset transistor ST1 via a contact portion. The fifth voltage line VL5 may apply the reset voltage Vrst (refer to FIG. 5) to the reset transistor ST1.

The connection patterns CNE11 to CNE18 may be spaced apart from each other when viewed in the plane and may be arranged in an island shape. In an embodiment, the connection patterns CNE11 to CNE18 may be referred to as connection electrodes and may electrically connect components connected to the connection electrode. The connection patterns CNE11 to CNE18 may include first, second, third, fourth, fifth, sixth, seventh, and eighth connection patterns CNE11, CNE12, CNE13, CNE14, CNE15, CNE16, CNE17, and CNE18.

The first connection pattern CNE11 may be connected to the second semiconductor pattern SP2 (refer to FIG. 9A) of the second transistor T2. As an example, the first connection pattern CNE11 may be connected to the source electrode S2 (refer to FIG. 9A) of the second transistor T2.

The second connection pattern CNE12 may be connected to the fifth semiconductor pattern SP5 of the fifth transistor T5 and the upper electrode UE (refer to FIG. 9C) via contact portions. As an example, the second connection pattern CNE12 may be connected to the source electrode S5 (refer to FIG. 9A) of the fifth transistor T5.

The third connection pattern CNE13 may be connected to the fourth semiconductor pattern SP4 (refer to FIG. 9D) of the fourth transistor T4 and the third voltage line VL3 (refer to FIG. 9C) via a contact portion. The source electrode S4 (refer to FIG. 9D) of the fourth transistor T4 may be electrically connected to the third voltage line VL3 (refer to FIG. 9C) via the third connection pattern CNE13 and may receive the first initialization voltage VINT1 (refer to FIG. 5) applied to the third voltage line VL3 (refer to FIG. 9C).

The fourth connection pattern CNE14 may be connected to the sixth semiconductor pattern SP6 (refer to FIG. 9A) of the sixth transistor T6. A portion of the fourth connection pattern CNE14 may correspond to the first connection electrode CNE1 of FIG. 6.

The fifth connection pattern CNE15 may be connected to the first gate electrode G1 (refer to FIG. 9B) of the first transistor T1 and the third semiconductor pattern SP3 (refer to FIG. 9D) of the third transistor T3 via contact portions. The first gate electrode G1 (refer to FIG. 9B) of the first transistor T1 may be electrically connected to the source electrode S3 (refer to FIG. 9D) of the third transistor T3 via the fifth connection pattern CNE15.

The sixth connection pattern CNE16 may be connected to the first semiconductor pattern SP1 (refer to FIG. 9A) of the first transistor T1 and the third semiconductor pattern SP3 (refer to FIG. 9D) of the third transistor T3 via contact portions. The drain electrode D1 (refer to FIG. 9A) of the first transistor T1 may be electrically connected to the drain electrode D3 (refer to FIG. 9D) of the third transistor T3 via the sixth connection pattern CNE16.

The seventh connection pattern CNE17 may be connected to the ninth semiconductor pattern SSP3 (refer to FIG. 9A) of the output transistor ST3. As an example, the seventh connection pattern CNE17 may be connected to the drain electrode SD3 (refer to FIG. 9A) of the output transistor ST3.

The eighth connection pattern CNE18 may be connected to the tenth semiconductor pattern SSP1 (refer to FIG. 9D) of the reset transistor ST1 and the gate electrode SG2 (refer to FIG. 9B) of the amplification transistor ST2 via contact portions. The drain electrode SD1 (refer to FIG. 9D) of the reset transistor ST1 may be electrically connected to the gate electrode SG2 (refer to FIG. 9B) of the amplification transistor ST2 via the eighth connection pattern CNE18. A portion of the eighth connection pattern CNE18 may correspond to the fourth connection electrode CNE1-1 of FIG. 6.

In an embodiment, the fourth conductive pattern layer MP4 may be spaced apart from and does not overlap the transmission area SA when viewed in the plane. For example, the transmission area SA may be spaced apart from the voltage lines VL4 and VL5 and the connection patterns CNE11 to CNE18 of the fourth conductive pattern layer MP4. Accordingly, the light traveling to the transmission area SA has a high probability of passing through the transmission area SA without being reflected.

Referring to FIG. 9G, a fifth conductive pattern layer MP5 may be disposed on the fourth conductive pattern layer MP4 (refer to FIG. 9F). The fifth conductive pattern layer MP5 may be disposed on the sixth insulating layer 60 (refer to FIG. 6). The fifth conductive pattern layer MP5 may include a voltage line VL1, a data line DL, read-out lines RL and RLa, and connection patterns CNE21 to CNE23.

The voltage line VL1 may extend in the first direction DR1 when viewed in the plane. The voltage line VL1 may correspond to the first voltage line VL1 of FIG. 5. The first voltage line VL1 may overlap at least a portion of the second connection pattern CNE12 (refer to FIG. 9F) when viewed in the plane and may be connected to the second connection pattern CNE12 via a contact portion.

The first voltage line VL1 may be electrically connected to the source electrode S5 (refer to FIG. 9A) of the fifth transistor T5 via the second connection pattern CNE12 (refer to FIG. 9F) and may provide the first driving voltage ELVDD (refer to FIG. 5) to the fifth transistor T5.

The first voltage line VL1 may be electrically connected to the upper electrode UE (refer to FIG. 9C) corresponding to the one end of the capacitor Cst (refer to FIG. 5) via the second connection pattern CNE12 (refer to FIG. 9F) and may provide the first driving voltage ELVDD (refer to FIG. 5) to the capacitor Cst (refer to FIG. 5).

The data line DL may extend in the first direction DR1 when viewed in the plane. The data line DL may overlap at least a portion of the first connection pattern CNE11 (refer to FIG. 9F) when viewed in the plane and may be connected to the first connection pattern CNE11 (refer to FIG. 9F) via a contact portion. The data line DL may be electrically connected to the source electrode S2 (refer to FIG. 9A) of the second transistor T2 via the first connection pattern CNE11 (refer to FIG. 9F) and may provide the data signal to the second transistor T2.

The data line DL may be provided in plural, and the data lines may be arranged spaced apart from each other in the second direction DR2. According to an embodiment, the transmission area SA may be defined between the data lines DL disposed adjacent to each other in the second direction DR2. However, a position where the transmission area SA is formed is not particularly limited as long as the transmission area SA is spaced apart from the signal lines in the display area.

The read-out lines RL and RLa may include a first read-out line RL and a second read-out line RLa. The first and second read-out lines RL and RLa may extend in the first direction DR1 when viewed in the plane.

Each of the first and second read-out lines RL and RLa may be disposed between the data lines DL spaced apart from each other in the second direction DR2. However, positions of the first and second read-out lines RL and RLa are not limited thereto.

The first read-out line RL and the second read-out line RLa may be spaced apart from each other in the second direction DR2. The first read-out line RL may be disposed farther away from the transmission area SA than the second read-out line RLa is. The first read-out line RL may have a continuous integral line shape.

The first read-out line RL may overlap at least a portion of the seventh connection pattern CNE17 (refer to FIG. 9F) when viewed in the plane and may be connected to the seventh connection pattern CNE17 (refer to FIG. 9F) via a contact portion. The first read-out line RL may be electrically connected to the drain electrode SD3 (refer to FIG. 9A) of the output transistor ST3 via the seventh connection pattern CNE17 (refer to FIG. 9F) and may receive the sensing signal Fsd (refer to FIG. 5) from the output transistor ST3.

The second read-out line RLa may include a first line R-1 and a second line R-2 spaced apart from the first line R-1 with the transmission area SA interposed therebetween. The second read-out line RLa disposed adjacent to the transmission area SA may be provided as plural lines R-1 and R-2 that are discontinued in an area corresponding to the transmission area SA not to degrade the light transmittance of the transmission area SA. Thus, the first line R-1 and the second line R-2 may be disposed not to overlap the transmission area SA.

The first and second lines R-1 and R-2 of the second read-out line RLa may be connected to each other via a connection line CNL (refer to FIG. 9H) described below. The first and second lines R-1 and R-2 connected to each other via the connection line CNL (refer to FIG. 9H) may form one read-out line and may be electrically connected to the light receiving element OPD (refer to FIG. 5) to receive the sensing signal Fsd (refer to FIG. 5) similar to the first read-out line RL. That is, the second read-out line RLa may extend in the first direction DR1 and may be electrically connected to the output transistor ST3 disposed adjacent to the transmission area SA.

The connection patterns CNE21 to CNE23 may be spaced apart from each other when viewed in the plane and may be arranged in an island shape. The connection patterns CNE21 to CNE23 may include ninth, tenth, and eleventh connection patterns CNE21, CNE22, and CNE23.

The ninth connection pattern CNE21 may be connected to the fourth connection pattern CNE14 (refer to FIG. 9F) via a contact portion. The ninth connection pattern CNE21 may be electrically connected to the sixth semiconductor pattern SP6 (refer to FIG. 9A) of the sixth transistor T6 via the fourth connection pattern CNE14 (refer to FIG. 9F). A portion of the ninth connection pattern CNE21 may correspond to the second connection electrode CNE2 of FIG. 6.

The tenth connection pattern CNE22 may be connected to the eighth connection pattern CNE18 (refer to FIG. 9F) via a contact portion. The tenth connection pattern CNE22 may be electrically connected to the tenth semiconductor pattern SSP1 (refer to FIG. 9D) of the reset transistor ST1 and the gate electrode SG2 (refer to FIG. 9B) of the amplification transistor ST2 via the eighth connection pattern CNE18 (refer to FIG. 9F). A portion of the tenth connection pattern CNE22 may correspond to the fifth connection electrode CNE2-1 of FIG. 6.

The eleventh connection pattern CNE23 may be connected to the fourth voltage line VL4 (refer to FIG. 9F) via a contact portion. According to an embodiment, the eleventh connection pattern CNE23 may be omitted.

In an embodiment, the fifth conductive pattern layer MP5 may be spaced apart from and does not overlap the transmission area SA when viewed in the plane. For example, the transmission area SA may be spaced apart from the voltage line VL1, the data line DL, the read-out lines RL and RLa, and the connection patterns CNE21 to CNE23 of the fifth conductive pattern layer MP5. Accordingly, the light traveling to the transmission area SA has a high probability of passing through the transmission area SA without being reflected.

Referring to FIG. 9H, a sixth conductive pattern layer MP6 may be disposed above the fifth conductive pattern layer MP5 (refer to FIG. 9G). The fifth conductive pattern layer MP5 may be disposed on the seventh insulating layer 70 (refer to FIG. 6). The sixth conductive pattern layer MP6 may include the connection line CNL and connection patterns CNE31a, CNE31b, CNE31c, and CNE32.

The connection line CNL may be connected to the first line R-1 and the second line R-2 of the fifth conductive pattern layer MP5 (refer to FIG. 9G) via contact portions. The connection line CNL may electrically connect the first and second lines R-1 and R-2 spaced apart from each other, and thus, may form one read-out line.

The connection line CNL may be disposed adjacent to the transmission area SA. The connection line CNL may be disposed along a periphery of the transmission area SA when viewed in the plane. That is, the connection line CNL may be placed to detour the transmission area SA without passing through the transmission area SA. Accordingly, in embodiments, deterioration of the light transmittance of the transmission area SA caused by the connection line CNL may be prevented.

Referring to FIG. 9H, the connection line CNL may extend along one side of the transmission area SA. As an example, the connection line CNL may include first portions respectively connected to the first line R-1 and the second line R-2 and extending in the second direction DR2 and a second portion extending in the first direction DR1 and connecting the first portions. However, a shape of the connection line CNL is not limited thereto.

FIG. 9I shows a sixth conductive pattern layer MP6a having substantially the same structure as that of the sixth conductive pattern layer MP6 of FIG. 9H, except a connection line CNLa.

Referring to FIG. 9I, the connection line CNLa may have a closed-line shape surrounding the transmission area SA. The connection line CNLa of FIG. 9I may have a quadrangular ring shape and may be spaced apart from the transmission area SA when viewed in the plane. However, the shapes of the connection lines CNL and CNLa shown in FIGS. 9H and 9I are merely examples, and the shapes of the connection lines CNL and CNLa are not particularly limited as long as the connection lines CNL and CNLa are placed to detour the transmission area SA.

Referring to FIGS. 9H and 9I, the connection lines CNL and CNLa may include, for example, a metal, alloy, conductive metal oxide, or transparent conductive material, and a material of the connection lines CNL and CNLa is not particularly limited as long as the connection lines CNL and CNLa have a conductivity. According to embodiments, even though the connection lines CNL and CNLa do not include the transparent conductive material, the light transmittance of the transmission area SA may be prevented from being deteriorated since the connection lines CNL and CNLa are placed to detour the transmission area SA. In addition, as the connection lines CNL and CNLa are disposed not to overlap the transmission area SA, there may be less limitations in selecting materials included in the connection lines CNL and CNLa, and the connection lines CNL and CNLa may include a metal material with a relatively low resistance. Therefore, a resistance of the second read-out line RLa connected to the connection lines CNL and CNLa is not reduced according to embodiments.

The connection patterns CNE31a, CNE31b, CNE31c, and CNE32 may be spaced apart from each other when viewed in the plane and may be arranged in an island shape. The connection patterns CNE31a, CNE31b, CNE31c, and CNE32 may include twelfth connection patterns CNE31a, CNE31b, and CNE31c and a thirteenth connection pattern CNE32.

The twelfth connection patterns CNE31a, CNE31b, and CNE31c may be respectively connected to the first electrodes (or anode electrodes) of the light emitting elements. Each of the twelfth connection patterns CNE31a, CNE31b, and CNE31c may be connected to a corresponding ninth connection pattern CNE21 (refer to FIG. 9G). Accordingly, each of the twelfth connection patterns CNE31a, CNE31b, and CNE31c may be electrically connected to the sixth semiconductor pattern SP6 (refer to FIG. 9A) of the sixth transistor T6 via the corresponding ninth connection pattern CNE21 (refer to FIG. 9G) and the fourth connection pattern CNE14 (refer to FIG. 9F). A portion of the twelfth connection patterns CNE31a, CNE31b, and CNE31c may correspond to the third connection electrode CNE3 of FIG. 6.

The twelfth connection patterns CNE31a, CNE31b, and CNE31c may include first, second, and third patterns CNE31a, CNE31b, and CNE31c. The light emitting elements respectively connected to the first, second, and third patterns CNE31a, CNE31b, and CNE31c may be disposed in the pixel areas that emit the lights having different colors.

The thirteenth connection pattern CNE32 may be connected to the sensing anode electrode of the light receiving element. The thirteenth connection pattern CNE32 may be connected to the tenth connection pattern CNE22 (refer to FIG. 9G). Accordingly, the thirteenth connection pattern CNE32 may be electrically connected to the gate electrode SG2 (refer to FIG. 9B) of the amplification transistor ST2 via the tenth connection pattern CNE22 (refer to FIG. 9G) and the eighth connection pattern CNE18 (refer to FIG. 9F). A portion of the thirteenth connection pattern CNE32 may correspond to the sixth connection electrode CNE3-1 of FIG. 6.

FIG. 9J shows a seventh conductive pattern layer MP7 disposed on the circuit layer DP_CL (refer to FIG. 6). Referring to FIG. 9J, the seventh conductive pattern layer MP7 may include first electrodes R_AE, G_AE, and B_AE of light emitting elements and a sensing anode electrode O_AE of a light receiving element.

The first electrodes R_AE, G_AE, and B_AE and the sensing anode electrode O_AE may be spaced apart from each other when viewed in the plane and may be arranged in an island shape. The sensing anode electrode O_AE may be disposed between the first electrodes R_AE, G_AE, and B_AE.

The first electrodes G_AE, B_AE, and R_AE may be respectively connected to the first, second, and third patterns CNE31a, CNE31b, and CNE31c (refer to FIG. 9I). Accordingly, each of the first electrodes R_AE, G_AE, and B_AE may be electrically connected to the sixth semiconductor pattern SP6 (refer to FIG. 9A) of the sixth transistor T6 via the corresponding ninth connection pattern CNE21 (refer to FIG. 9G) and the fourth connection pattern CNE14 (refer to FIG. 9F).

The first electrode G_AE connected to the first pattern CNE31a may be disposed to correspond to the pixel area emitting the first color light. The first electrode B_AE connected to the second pattern CNE31b may be disposed to correspond to the pixel area emitting the second color light. The first electrode R_AE connected to the third pattern CNE31c may be disposed to correspond to the pixel area emitting the third color light. In this case, the first, second, and third color lights may have different colors from each other.

The sensing anode electrode O_AE may be connected to the thirteenth connection pattern CNE32 (refer to FIG. 9H). Accordingly, the sensing anode electrode O_AE may be electrically connected to the gate electrode SG2 (refer to FIG. 9B) of the amplification transistor ST2 via the thirteenth connection pattern CNE32 (refer to FIG. 9H), the tenth connection pattern CNE22 (refer to FIG. 9G), and the eighth connection pattern CNE18 (refer to FIG. 9F).

The transmission area SA may be spaced apart from the first electrodes R_AE, G_AE, and B_AE, and the sensing anode electrode O_AE and may be disposed between the first electrodes R_AE, G_AE, and B_AE. Accordingly, the transmission area SA may have a high light transmittance while not affecting the image output from the light emitting elements.

The electronic device may include the display panel and the optical sensor disposed under the display panel. The optical sensor may overlap the transmission area of the display panel. The signal lines disposed adjacent to the transmission area of the display panel may be electrically connected to each other via the connection line disposed along the periphery of the transmission area and do not overlap the transmission area in embodiments. Therefore, the transmittance of the transmission area may be increased. As the signal lines disposed adjacent to the transmission area are not disposed in the transmission area, the signal lines and the connection line may be formed of not only the transparent conductive material, but also the metal material with the low resistance. Accordingly, in embodiments, the signal lines do not cause deterioration in the light transmittance of the transmission area, and the resistance of the signal lines is not reduced.

While the present disclosure has been particularly shown and described with reference to embodiments thereof, it will be understood by those of ordinary skill in the art that various changes in form and detail may be made therein without departing from the spirit and scope of the present disclosure as defined by the following.

What is claimed is:

1. An electronic device, comprising:
a display panel comprising a transmission area and a display area disposed adjacent to the transmission area,
wherein an image is displayed in the display area; and
an optical sensor overlapping the transmission area and disposed under the display panel, wherein the display panel comprises:
a light emitting element disposed in the display area;
a light receiving element disposed in the display area;
a plurality of signal lines electrically connected to the light emitting element or the light receiving element; and
a connection line disposed along a periphery of the transmission area,
wherein at least one of the signal lines comprises a first line and a second line spaced apart from the first line with the transmission area interposed therebetween, and the connection line is connected to each of the first line and the second line.

2. The electronic device of claim 1, wherein the connection line extends along one side of the transmission area.

3. The electronic device of claim 1, wherein the connection line has a closed-line shape surrounding the transmission area.

4. The electronic device of claim 1, wherein the connection line comprises a metal material.

5. The electronic device of claim 1, wherein the connection line comprises an optically transparent conductive material.

6. The electronic device of claim 1, wherein the connection line comprises a same material as the first and second lines.

7. The electronic device of claim 1, wherein the first line and the second line are disposed on a same layer, and the connection line is disposed on a layer different from the first and second lines and connected to each of the first and second lines via a contact hole.

8. The electronic device of claim 1, wherein the light emitting element is one of a plurality of light emitting elements, and the transmission area is disposed between the light emitting elements.

9. The electronic device of claim 8, wherein the light receiving element is one of a plurality of light receiving elements, and each of the light receiving elements is disposed between the light emitting elements and spaced apart from the transmission area.

10. The electronic device of claim 1,
wherein the light emitting element comprises:
a first electrode;
a second electrode disposed on the first electrode; and
a light emitting layer disposed between the first electrode and the second electrode,
wherein the light receiving element comprises:
a sensing anode electrode disposed on a same layer as the first electrode;
a sensing cathode electrode disposed on the sensing anode electrode; and
a photoelectric conversion layer disposed between the sensing anode electrode and the sensing cathode electrode.

11. The electronic device of claim 1, wherein the display panel further comprises:
a pixel definition layer through which a light emitting opening, a light receiving opening, and a transmission opening, which are spaced apart from each other, are defined,
wherein the light emitting element corresponds to the light emitting opening, the light receiving element corresponds to the light receiving opening, and the transmission opening overlaps the transmission area.

12. The electronic device of claim 1, wherein the signal lines comprise:
a data line electrically connected to the light emitting element; and
a read-out line electrically connected to the light receiving element,
wherein each of the data line and the read-out line extends in one direction, and the data line and the read-out line are arranged spaced apart from each other in a direction intersecting the one direction.

13. The electronic device of claim 12, wherein the data line and the read-out line are disposed on a same layer.

14. The electronic device of claim 12, wherein the first line and the second line are connected to each other via the connection line, and the first line and the second line correspond to the read-out line.

15. An electronic device, comprising:
a display panel comprising a transmission area; and
an optical sensor overlapping the transmission area, wherein the display panel comprises:
a circuit layer; and
an element layer disposed on the circuit layer and comprising a plurality of light emitting elements and a plurality of light receiving elements, wherein the circuit layer comprises:
a pixel driving circuit electrically connected to each of the light emitting elements;
a sensor driving circuit electrically connected to each of the light receiving elements;
a data line electrically connected to the pixel driving circuit;
a read-out line electrically connected to the sensor driving circuit; and
a connection line connected to the read-out line,
wherein the transmission area is disposed between the light emitting elements when viewed in a plane,
wherein the transmission area is spaced apart from the pixel driving circuit, the sensor driving circuit, the data line, the read-out line, and the connection line, and the connection line is disposed along a periphery of the transmission area.

16. The electronic device of claim 15, wherein the display panel further comprises:
a display area in which an image is displayed,
wherein the data line and the read-out line extend in one direction in the display area and are spaced apart from each other in a direction intersecting the one direction.

17. The electronic device of claim 16, wherein the read-out line comprises:
a first line and a second line spaced apart from the first line with the transmission area interposed therebetween,
wherein the first line is electrically connected to the second line via the connection line.

18. The electronic device of claim 15, wherein the connection line extends along one side of the transmission area.

19. The electronic device of claim 15, wherein the connection line has a closed-line shape surrounding the transmission area.

20. The electronic device of claim 15,
wherein each of the light emitting elements comprises:
a first electrode;
a second electrode disposed on the first electrode; and
a light emitting layer disposed between the first electrode and the second electrode,
wherein each of the light receiving element comprises:
a sensing anode electrode disposed on a same layer as the first electrode;
a sensing cathode electrode disposed on the sensing anode electrode; and
a photoelectric conversion layer disposed between the sensing anode electrode and the sensing cathode electrode.
